(19) United States
(12) Patent Application Publication
(10) Pub. No.: US 2020/0265174 A1
(43) Pub. Date: Aug. 20, 2020

(54) UNIT DEVICE TO DESIGN A BUILDING SYSTEM AND A METHOD OF FORMING A UNIT DEVICE

(71) Applicant: Katerra Inc., Menlo Park, CA (US)

(72) Inventors: Jay MARTIN, Bainbridge Island, WA (US); Peter SPRUANCE, Seattle, WA (US); Hill PIERCE, Seattle, WA (US); Josh LAFRENIERE, Seattle, WA (US); Libby SO, Seattle, WA (US); Peter WOLFF, Seattle, WA (US); Shane HERZER, Seattle, WA (US); Leroy TUNG, Seattle, WA (US); Katie BLESSER, Seattle, WA (US); David REDDING, Seattle, WA (US); Eric ROBERTS, Seattle, WA (US); Matthew Marc GRUNERT, Seattle, WA (US); Kristin JENSEN, Seattle, WA (US); Cameron MARSHALL, Seattle, WA (US); Shannon QIN, Seattle, WA (US); Christine KIEFER, Seattle, WA (US); Queena YI, Seattle, WA (US); Mike Dickson MILLS, Chapel Hill, NC (US); Eva TALBOT, Seattle, WA (US); Roumeng WANG, Seattle, WA (US); Rochelle HILL, Burlington, WA (US); Lief FRIEDRICHS, Seattle, WA (US); Robert SMITH, Chandler, AZ (US); Linda COPPA, Seattle, WA (US); Luis Pascual RODENAS GARCIA, Austin, TX (US); Austin CUDWORTH, Seattle, WA (US); Ethan JENNERICH, Seattle, WA (US); Aubrey DAVIDSON, Seattle, WA (US); Sean DARNELL, Seattle, WA (US); Michael WEINERT, Seattle, WA (US); Aaron SCOTT, Seattle, WA (US); Gabriela GERINSKA, Seattle, WA (US); Michelle HA, Seattle, WA (US); Sam GIOIA, Colorado Springs, CO (US); Joe LLONA, Lynwood, WA (US); Nadav BITTAN, Seattle, WA (US)

(73) Assignee: Katerra Inc., Menlo Park, CA (US)

(21) Appl. No.: 16/794,014

(22) Filed: Feb. 18, 2020

Related U.S. Application Data
(60) Provisional application No. 62/806,714, filed on Feb. 15, 2019.

(51) Int. Cl. G06F 30/13; E04H 1/04; E04H 1/00

(52) U.S. Cl. CPC G06F 30/13; E04B 2001/0053; E04H 1/005; E04H 1/04

(57) ABSTRACT

A user configurable modular building system is provided. The user configurable modular building system includes a plurality of assemblies, a plurality of units, and a plurality of blocks. The plurality of assemblies includes a plurality of building components that perform building functions. Assemblies are selected from the plurality of assemblies to form a plurality of units. The plurality of units includes studio, one bedroom, and two bedroom units with different layouts of the selected assemblies. Units are selected from the plurality of units to form a plurality of blocks. The blocks are portions of a building. Blocks are selected to form the building based on a mix and layout of units. A method of designing a building system and a non-transitory computer-readable medium configured to perform steps to design a building system are also provided.

### CROSS REFERENCE TO RELATED APPLICATION

This application claims the benefit of U.S. Provisional Application No. 62/806,714 for UNITIZED BUILDING SYSTEM filed on Feb. 15, 2019, which are incorporated by reference as if fully set forth.

### FIELD OF INVENTION

The present invention relates generally to the art of construction, and more specifically to a building system, and a method of assembly thereof.

### BACKGROUND

The design of a building is a tedious and time consuming process. Buildings are designed from the ground up. Each design phase of the building is designed from scratch, wherein each design task starts anew at the beginning of each new project. Floor plans, building form, window type and size, external finishes, mechanical, electrical, and plumbing (MEP) systems, interior design, number and size of apartments, layout of the apartments, stairs and/or elevators, etc. are all determined during the design process of an apartment complex. Because each of these design decisions must be made for each new project, the design process for a new project takes a very long time. Moreover, many of these design decisions are codependent and therefore must be made in succession. Thus, many design decisions cannot be made until far along in the design process. The design of an apartment building is complex and would benefit from a system that balances standardization and flexibility to streamline the process yet allow customers to customize the building for their needs.

### SUMMARY

A user configurable modular building system is provided. The user configurable modular building system includes a plurality of assemblies, a plurality of units, and a plurality of blocks. Each assembly of the plurality of assemblies is configured to perform a building function. The plurality of assemblies represents a plurality of different building functions with multiple assemblies of the plurality of assemblies configured to serve the same building function. The building function is general or specific. The plurality of assemblies serves building functions of a complete fully functional building.

Each unit of the plurality of units has a design including general and specific building functions. Assemblies from the plurality of assemblies are selected to perform the general and specific building functions of the unit. One assembly is selected for each specific building function and multiple assemblies are selected for each general building function. The plurality of units has different square footages and different layouts of the selected assemblies. A first set of units of the plurality of units are studio units. A second set of units of the plurality of units are one bedroom units. A third set of units of the plurality of units are two bedroom units.

Each block of the plurality of blocks is configured to represent a portion of a building. The block includes at least two units from the plurality of units.

User selected blocks from the plurality of blocks are combined to form the building.

A method for designing a building system is also provided. The method includes forming a plurality of assemblies, forming a plurality of units, forming a plurality of blocks, selecting blocks from the plurality of blocks, and combining the selected blocks to form the building.

Each assembly of the plurality of assemblies is configured to perform a building function. The plurality of assemblies represents a plurality of different building functions with multiple assemblies of the plurality of assemblies configured to serve the same building function. The building function is general or specific. The plurality of assemblies serves building functions of a complete fully functional building.

Each unit of the plurality of units has a design including general and specific building functions. Assemblies from the plurality of assemblies are selected to perform the general and specific building functions of the unit. One assembly is selected for each specific building function and multiple assemblies are selected for each general building function. The plurality of units has different square footages and different layouts of the selected assemblies. A first set of units of the plurality of units are studio units. A second set of units of the plurality of units are one bedroom units. A third set of units of the plurality of units are two bedroom units.

Each block of the plurality of blocks is configured to represent a portion of a building. The block includes at least two units from the plurality of units.

A non-transitory computer-readable medium comprising a computer program product recorded thereon and capable of being run by a processor, including program code instructions for a process for designing a building system by implementing steps is also provided. The steps implemented comprising forming a plurality of assemblies, forming a plurality of units, forming a plurality of blocks, selecting blocks from the plurality of blocks, and combining the selected blocks to form the building.

Each assembly of the plurality of assemblies is configured to perform a building function. The plurality of assemblies represents a plurality of different building functions with multiple assemblies of the plurality of assemblies configured to serve the same building function. The building function is general or specific. The plurality of assemblies serves building functions of a complete fully functional building.

Each unit of the plurality of units has a design including general and specific building functions. Assemblies from the plurality of assemblies are selected to perform the general and specific building functions of the unit. One assembly is selected for each specific building function and multiple assemblies are selected for each general building function. The plurality of units have different square footages and different layouts of the selected assemblies. A first set of units of the plurality of units are studio units. A second set of units of the plurality of units are one bedroom units. A third set of units of the plurality of units are two bedroom units.

Each block of the plurality of blocks is configured to represent a portion of a building. The block includes at least two units from the plurality of units.

A block device is also provided. The block device includes a plurality of assemblies and a plurality of units. Each assembly of the plurality of assemblies is configured to perform a building function. The plurality of assemblies represents a plurality of different building functions with multiple assemblies of the plurality of assemblies configured to serve the same building function. The building function is general or specific. The plurality of assemblies serves building functions of a complete fully functional building.

Each unit of the plurality of units has a design including general and specific building functions. Assemblies from the plurality of assemblies are selected to perform the general and specific building functions of the unit. One assembly is selected for each specific building function and multiple assemblies are selected for each general building function. The plurality of units includes at least one of a studio unit, a one bedroom unit, and a two bedroom unit.

The plurality of units is combined to form a portion of a building.

A method of forming a block device is also provided. The method includes forming a plurality of assemblies, forming a plurality of units, selecting units form the plurality of units, and combining the selected units.

Each assembly of the plurality of assemblies is configured to perform a building function. The plurality of assemblies represents a plurality of different building functions with multiple assemblies of the plurality of assemblies configured to serve the same building function. The building function is general or specific. The plurality of assemblies serves building functions of a complete fully functional building.

Each unit of the plurality of units has a design including general and specific building functions. Assemblies from the plurality of assemblies are selected to perform the general and specific building functions of the unit. One assembly is selected for each specific building function and multiple assemblies are selected for each general building function. The plurality of units includes at least one of a studio unit, a one bedroom unit, and a two bedroom unit.

A non-transitory computer-readable medium comprising a computer program product recorded thereon and capable of being run by a processor, including program code instructions for a process for creating a block by implementing steps is also provided. The steps implemented comprising forming a plurality of assemblies, forming a plurality of units, selecting units form the plurality of units, and combining the selected units.

Each assembly of the plurality of assemblies is configured to perform a building function. The plurality of assemblies represents a plurality of different building functions with multiple assemblies of the plurality of assemblies configured to serve the same building function. The building function is general or specific. The plurality of assemblies serves building functions of a complete fully functional building.

Each unit of the plurality of units has a design including general and specific building functions. Assemblies from the plurality of assemblies are selected to perform the general and specific building functions of the unit. One assembly is selected for each specific building function and multiple assemblies are selected for each general building function. The plurality of units includes at least one of a studio unit, a one bedroom unit, and a two bedroom unit.

A unit device is also provided. The unit device including a plurality of assemblies. Each assembly of the plurality of assemblies is configured to perform a general building function or a specific building function. Multiple assemblies perform the same general building function and one assembly performs each specific building function. The plurality of assemblies is combined to form at least one of a studio unit, a one bedroom unit, and a two bedroom unit.

A method of forming a unit device is also provided. The method including forming a plurality of assemblies, selecting assemblies from the plurality of assemblies, and combining the selected assemblies to form at least one of a studio unit, a one bedroom unit, and a two bedroom unit.

Each assembly of the plurality of assemblies is configured to perform a general building function or a specific building function. Multiple assemblies perform the same general building function and one assembly performs each specific building function.

A non-transitory computer-readable medium comprising a computer program product recorded thereon and capable of being run by a processor, including program code instructions for a process for creating a unit by implementing steps is also provided. The steps implemented comprising forming a plurality of assemblies, selecting assemblies from the plurality of assemblies, and combining the selected assemblies to form at least one of a studio unit, a one bedroom unit, and a two bedroom unit.

Each assembly of the plurality of assemblies is configured to perform a general building function or a specific building function. Multiple assemblies perform the same general building function and one assembly performs each specific building function.

An assembly device is also provided. The assembly device including a plurality of building components. The building components are configured to define the assembly device to a particular function with a building. The building is comprised of a plurality of units. The plurality of units is formed by combining the plurality of building components to form a habitable dwelling.

A computer system for creating an assembly library is also provided. The computer system includes a processor and a memory. The processor and memory device are configured to cooperatively maintain a library of assemblies including a plurality of building components. The building components are configured to define the assembly device to a particular function within a building. The processor and memory device are configured to cooperatively select and combine building components from the plurality of building components to form a plurality of assemblies. The plurality of assemblies is configured to form a plurality of units. The plurality of units includes at least one of a studio unit, a one bedroom unit, and a two bedroom unit.

### BRIEF DESCRIPTION OF THE DRAWINGS

The foregoing summary, as well as the following detailed description will be better understood when read in conjunction with the appended drawings. For the purpose of illustration, there is shown in the drawings different embodiments. It should be understood, however, that the teachings are not limited to the precise building system shown.

FIG. 1 shows a flow chart of the anatomy of at least one building project.

FIG. 2 shows a diagram of the unitized building system.

FIG. 3 is a figure of the site category of assemblies.

FIG. 4A depicts a general slab and stem foundation.

FIG. 4B shows a shallow foundation.

FIG. 4C shows a post-tensioned slab on grade.

FIG. 4D shows a deep foundation.

FIG. 5A is a figure of the floor category of assemblies.

FIG. 5B shows a cross-section of a floor panel.

FIG. 5C shows a cross-section of a wood floor panel.

FIG. 5D shows a cross-section of a cold formed steel (CFS) floor panel.

FIG. 6 is a figure of the wall category of assemblies.

FIG. 7A a figure of the roof category of assemblies.

FIG. 7B shows a cross-section of the first solution including parapets.

FIG. 7C show a perspective view of the first solution including parapets.

FIG. 7D shows a cross-section of the second solution including a gable with eaves.

FIG. 7E shows a perspective view of the second solution including a gable with eaves.

FIG. 8A is a figure of the fenestration category of assemblies.

FIG. 8B shows a window.

FIG. 8C shows a window and air condition configuration.

FIG. 8D shows a sliding door and air condition configuration.

FIG. 9A is a figure of the enclosure category of assemblies.

FIG. 9B shows lap sliding, board and batten, large format panels, horizontal panels, metal appearance, wood or thermally modified wood, a first option for metal panel, a second option for metal panel, and stucco.

FIG. 10A is a figure of the exterior accessory category of assemblies.

FIG. 10B shows a picket railing option.

FIG. 10C shows a welded mesh infill railing option.

FIG. 10D shows a perforated infill railing.

FIG. 10E shows a glass infill railing option.

FIG. 10F shows a balcony attached to the exterior of a wall.

FIG. 11A is a figure of the vertical conveyance category of assemblies.

FIG. 11B shows a hoistway or cab plan.

FIG. 11C shows an elevator or shaft section.

FIG. 11D shows a perspective view of a four level stairway.

FIG. 11E shows the ground level plan.

FIG. 11F shows the first floor level plan.

FIG. 11G shows the second floor level plan.

FIG. 1111 shows the third floor level plan.

FIG. 12A is a figure of the exterior accessory category of assemblies.

FIG. 12B shows the first level of an MEP system.

FIG. 12C shows the middle level of an MEP system.

FIG. 12D shows the top level of an MEP system.

FIG. 13A is a figure of the terminal utilities category of assemblies.

FIG. 13B shows a shaft assembly.

FIG. 13C shows an electrical load center assembly.

FIG. 14A is a figure of the casework category of assemblies.

FIG. 14B shows closet accessories including hanging rods, accessory trays, jewelry trays, trousers racks, show racks, clothing baskets, tie racks, pull-out mirrors, and pull-down hanging rods.

FIG. 15A is a figure of the kitchen category of assemblies.

FIG. 15B shows a first kitchen.

FIG. 15C show example kitchens.

FIG. 15D show example kitchen islands.

FIG. 16A is a figure of the bathroom category of assemblies.

FIG. 16B shows a first bathroom plan.

FIG. 16C shows a second bathroom plan.

FIG. 16D shows an exploded view of the bathroom kit.

FIG. 16E shows a bathroom kit.

FIG. 17A is a figure of the interior finish category of assemblies.

FIG. 17B shows interior finishes.

FIG. 17C shows lighting elements.

FIG. 17D shows appliances.

FIG. 18 shows a flow chart for creating an assembly library.

FIG. 19 shows a unit.

FIG. 20 shows an optimized unit.

FIG. 21A shows plans of studio or guest suite units.

FIG. 21B shows plans of one bedroom units.

FIG. 21C shows a plan of a one bedroom with a den or two bedrooms with one bath unit.

FIG. 21D shows plans of two bedroom units.

FIG. 21E shows a plan a three bedroom unit.

FIG. 22A shows floor panel plans for the units shown in FIG. 21A.

FIG. 22B shows floor panel plans for the units shown in FIG. 21B.

FIG. 22C shows a floor panel plan for the unit shown in FIG. 21C.

FIG. 22D shows floor panel plans for the units shown in FIG. 21D.

FIG. 22E shows a floor panel plan for the unit shown in FIG. 21E.

FIG. 23A shows garage plans for the units shown in FIG. 21A.

FIG. 23B shows garage plans for the units shown in FIG. 21B.

FIG. 23C shows a garage plan for the unit shown in FIG. 21C.

FIG. 23D shows garage plans for the units shown in FIG. 21D.

FIG. 23E shows a garage panel plan for the unit shown in FIG. 21E.

FIG. 24 shows a flow chart for forming a unit.

FIG. 25 shows a block.

FIG. 26A shows a perspective view of a block library for a corridor style building.

FIG. 26B shows plans of blocks in a block library for a corridor style building.

FIG. 27A shows three studio unit in-line block options.

FIG. 27B shows three one bedroom unit in-line block options.

FIG. 27C shows five two bedroom unit in-line block options.

FIG. 27D shows an in-line block including a stair unit, a one bedroom unit, and a two bedroom unit.

FIG. 28A shows perspective views of the end blocks.

FIG. 28B shows a plan view of an end block.

FIG. 29A shows perspective views of the corner block options.

FIG. 29B shows a plan view of a corner block.

FIG. 30A shows a plan view of a first corner block option.

FIG. 30B shows a plan view of a second corner block option.

FIG. 30C shows a plan view of a third corner block option.

FIG. 30D shows a plan view a fourth corner block option

FIG. 31 depicts a slot block plan option.

FIG. 32 shows an amenity block.

FIG. 33A shows a plan for an amenity block which fits in an end block below units.

FIG. 33B shows a plan for an amenity block which fits in an in-line block below units.

FIG. 33C shows an amenity block which may form a central block.

FIG. 34 shows a block library for a garden style building.

FIG. 35A shows an example block options for levels 2 and up.

FIG. 35B shows an example block option for the first level.

FIG. 35C shows an example block option for a tuck-under level.

FIG. 36A show end block plans for levels 1 and up.

FIG. 36B show end block plans for the tuck-under level.

FIG. 37 shows a flow chart for a method to form a block.

FIG. 38 shows a building system.

FIG. 39 shows a diagram of a building system work flow chart.

FIG. 40 shows a flow chart of the design process for the building system.

FIG. 41 shows a flow chart of a method of designing a building system.

FIG. 42A shows a perspective view and a plan view of a linear corridor style building.

FIG. 42B shows a perspective view and a plan view of an “L” shaped corridor style building.

FIG. 43 shows the base building options for garden style buildings using the predefined central blocks, first end blocks, and second end blocks.

FIG. 44 is an example computing device that may be used to implement features described herein.

### DETAILED DESCRIPTION

A method, apparatus, and software utilizing a unitized building system for constructing unitized buildings is disclosed. The building system includes a building comprised of blocks. Each block is comprised of units. Each unit is comprised of assemblies and designed based on requirements such as number of bedrooms, square footage, etc. Units are built from prefabricated panels and kits, such as wall and floor panels and bathroom and kitchen kits. The various kits such as floors, walls, windows, baths, kitchens, utility closets, mechanical, electrical and plumbing (MEP), and wall panels make up an assembly library. Various units meeting different needs make up a unit library. A combination of units are selected and connected to create various blocks. Various blocks meeting different needs make up a block library. Blocks are selected and assembled based on site information and initial development targets. The blocks are combined and connected into buildings. Any type of building or structure may be designed and built pursuant to the teachings herein. Similarly, any type of building material may be used when implementing the teachings herein.

Units are designed and built from its basic constituents. A unit can be an apartment, or any other type of building component. The unit is determined from requirements (e.g. studio, 1 br, 2 br, etc.) and square footage (e.g. zoning, viable product, etc.). The units are defined using kits from an assembly library. Then, the mechanical interconnectivity/interface between units is defined. Said units are elements in the unit library. Any number of units may be chosen to create a block.

Buildings, such as an apartment building, are built from predefined blocks. Geographical and site data, such as the map of the land, height limitations, zoning restrictions, geological restrictions etc. are collected. The layout of the building outline is determined. Then, the timeline or building schedule and the staging area are determined, which may evolve as the building is constructed. From the layout of the building, a program may be selected. The desired blocks are selected containing selected units from the unit library based upon the desired configuration. Other options such as finishes may also be selected and customized. The blocks are configured to form the building. A bill of materials may be generated at a unit level and/or at an assembly level, for example. Work orders are generated based upon the construction order. These work orders include orders to factories and orders pertaining to the site preparation such as foundation and utility preparation. The method and apparatus described herein enable fast and cost-efficient design of buildings.

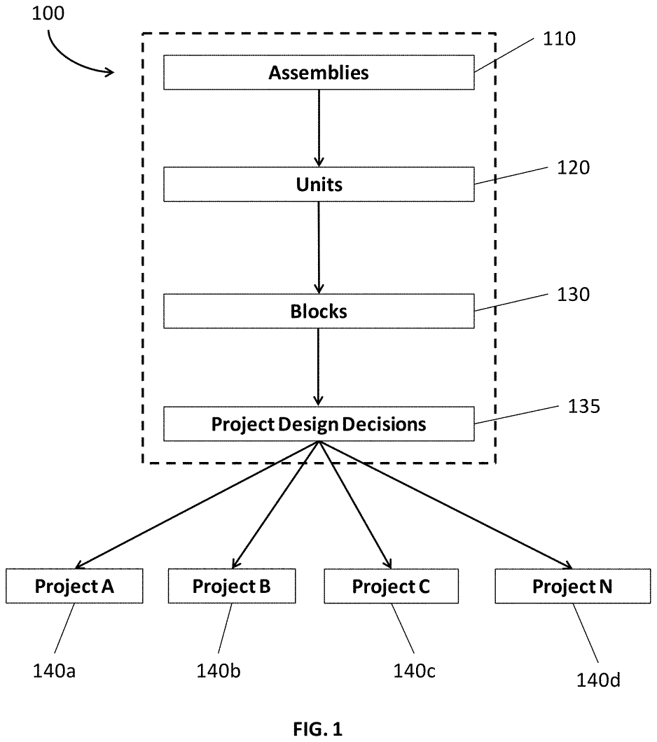

FIG. 1 shows a flow chart 100 of the anatomy of at least one building project 140a-d. Each project 140a-d may be the construction of a building, such as an apartment complex. The first component of the project comprises assemblies 110. A known set of manufactured assemblies 110 make up an assembly library. The assemblies 110 are comprised of known parts and are the primary vehicle for incorporating sourced materials and arriving at a final bill of materials. Assemblies 110 may be organized by fifteen classification categories of common building components described herein.

Units 120 are comprised of one or more assemblies 110 from the assembly library. Different units 120 make up a unit library. Projects 140a-d may tailor a mix of the units 120 from the unit library that are to be included. Unit 120 options may include accessibility standards, interior finishes by price tier, and defined fenestration and balcony choices.

Blocks 130 are comprised of one or more units 120 from the unit library. Different blocks 130 make up a block library. The block library establishes building form and facilitates the rapid development of coordinated buildings. Planning blocks 130 establish the product rule set and are provided to project teams for initial site planning.

Project design decisions 135 are made to create a final customized building. The final product is developed to accelerate project schedules and arrive at a known set of manufactured assemblies as outlined herein. Projects A-N 140a-d are sent out for construction.

This system balances standardization by using prefabricated assemblies to form predefined units, the predefined units are combined to form predefined blocks. The predefined blocks may be user selected to create a building. However, certain building components are customizable to the specific building project, thereby creating a balance of standardization and flexibility. This system may be used to generate multiple projects and eliminates the need to start anew with each new project. Additionally, because the blocks used to design the buildings are predefined, many design decisions are decided early on and the overall design process is much shorter and less time consuming.

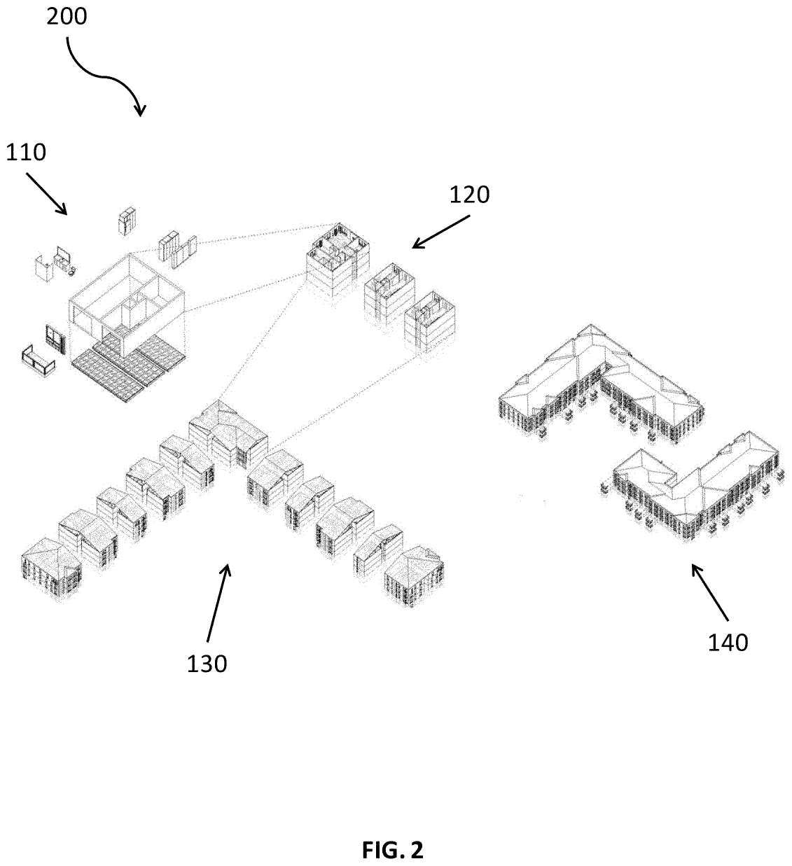

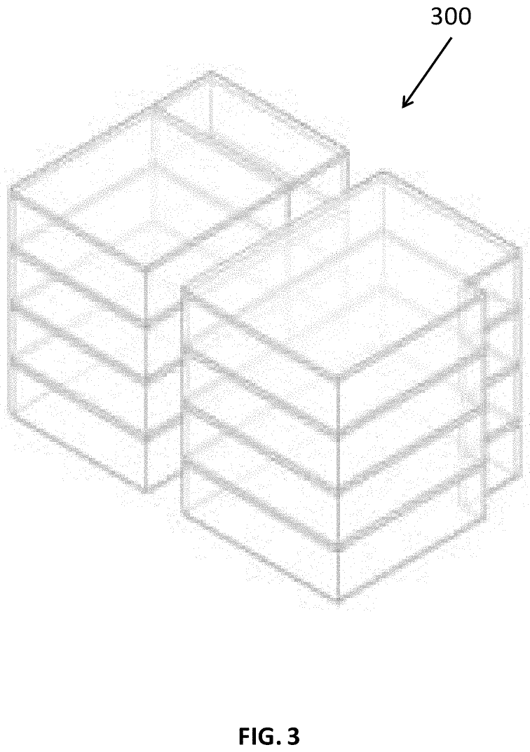

FIG. 2 shows a diagram of the unitized building system 200. The diagram depicts the hierarchy of the components. The first level component includes the assemblies 110. The assemblies 110 are assembled into units 120. The units 120 are assembled into blocks 130. Finally, the blocks 130 are assembled into buildings 140. The numerous options of assemblies 110 may be chosen to make a number of different units 120. The different units 120 may be combined in multiple ways to create many different blocks 130, and the many different blocks 130 can be assembled in different ways to create many different building 140 options.

The assemblies 110 may be organized into fifteen different categories of common building components. The categorization system is intended to align design, sourcing, estimating, manufacturing and construction around a panelized or modular approach to making buildings. The fifteen categories of assemblies may include site 300, foundation 400, floor 500, wall 600, roof 700, fenestration 800, enclosure 900, exterior accessory 1000, vertical conveyance 1100, building mechanical, electrical and plumbing (MEP) 1200, terminal utilities 1300, casework 1400, kitchen 1500, bathroom 1600, and interior finish 1700. The strategy for each of the fifteen categories is to strike a balance between standardization and flexibility. The assemblies 110 in the fifteen categories may be considered “standard,” “configurable,” “automated,” or “custom.” “Standard” elements are fixed by the building system. “Configurable” elements have options within the building system. “Automated” elements are unique to the projects but are quickly resolved in the design process. “Custom” elements are project specific and must be resolved.

Assemblies 110 perform the building functions of a completed building 140. The building functions may be specific functions or general functions. Further the functions may be implemented at the unit 120 level, the block 130 level, or the building 140 level. A specific function is one in which a single assembly can perform. A general function is one in which multiple assemblies are required to perform. For example wall panel and floor panels are general functions. Bathrooms and kitchens are specific functions.

Assemblies

FIG. 3 is a figure of the site 300 category of assemblies 110. The site category consists of “custom” elements. Feasibility blocks facilitate site planning. Feasibility blocks are simplified three dimensional representations of the building configuration. A feasibility blocks is a defined aggregation of units 120 which may fit into a given site layout. A block may be defined by orientation, block shape, height, footprint, total area, total volume and number of bedrooms. Site plans are designed using the product's feasibility blocks. The site plans layout the size, shape, and space of the building. The site plans are dependent on the land, square footage, building function, etc. Feasibility blocks allow for varied building forms and unit mixes while ensuring the resulting buildings 140 adhere to system rules and are comprised of known assemblies 110. The parameters contained within the feasibility block families allow a number of decisions to be made early in the design process.

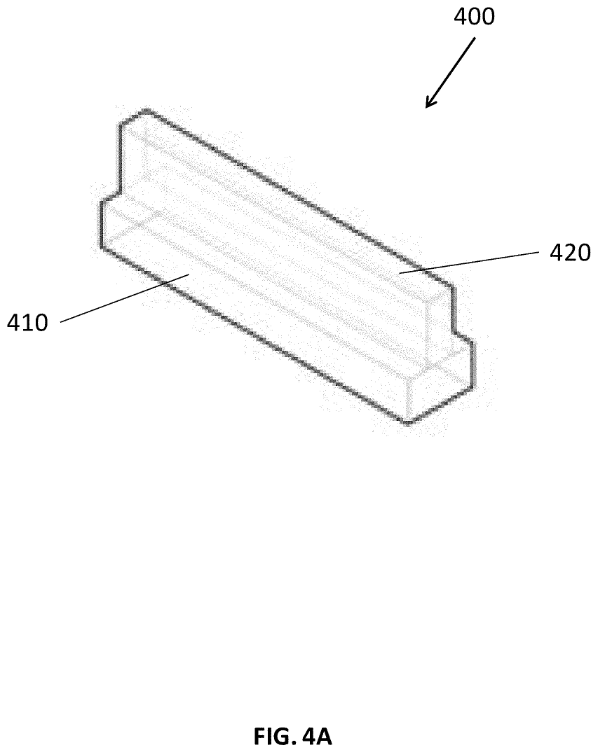

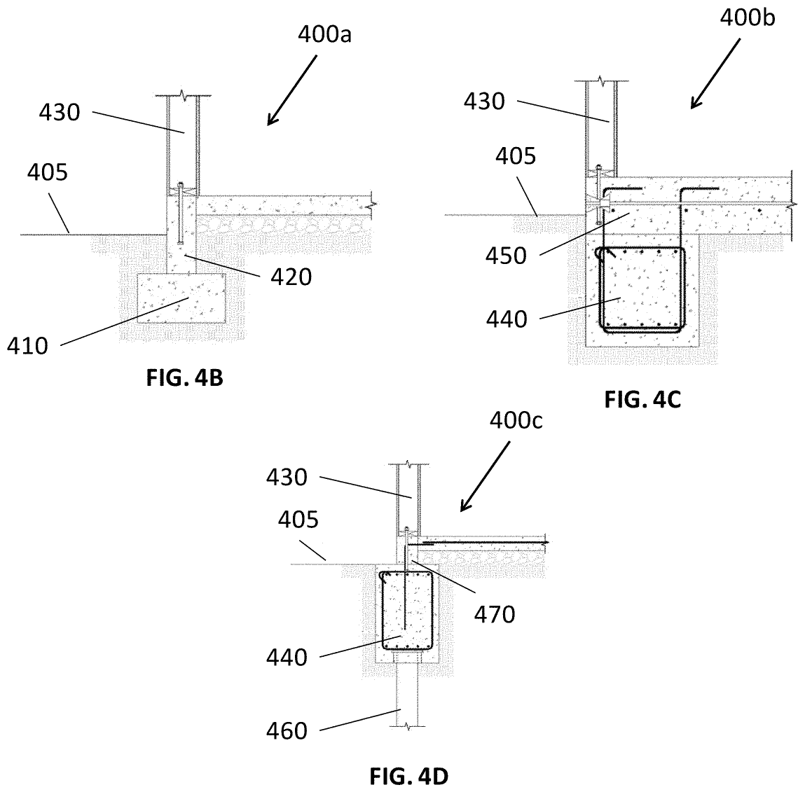

FIGS. 4A-4D are exemplary figures of the foundation 400 category of assemblies 110. FIG. 4A depicts a general slab 410 and stem 420 foundation 400. The foundation 400 category consists of “custom” elements. The foundation 400 is based on site 300 conditions and building design. Building foundations 400 are designed specifically for each site 300 on a project-by-project basis. Analysis tools and processes are standardized and quickly generate foundation designs. Standard engineering practices are used to design the foundation. FIGS. 4B-4D show three types of foundations 400 that may be used.

FIG. 4B shows a shallow foundation 400a. The shallow foundation 400a includes a concrete stem 420 and slab 410 extending past the top of grade 405. The exterior wall 430 is constructed on the concrete stem 420 and slab 410. A shallow foundation 400a may be used with dense sands or gravels and stiff silts and clays. The shallow foundations 400a may be micro-fiber reinforced slab on grade with stem walls and grade beams, or thick micro-fiber reinforced uniform slab.

FIG. 4C shows a post-tensioned slab on grade foundation 400b. The post-tensioned slab on grade foundation 400b includes a concrete grade beam 440 connected to a post-tensioned concrete slab 450 on the top of grade 405. The exterior wall 430 is constructed on the post-tensioned concrete slab 450. Post-tensioned slab on grade 400b may be used for sites with expansive clays or sites with localized deep pockets of loose soils. This type of foundation 400b typically requires the top three to five feet below grade to be replaced with a structural fill pad. The foundation 400b also typically requires moisture conditioning.

FIG. 4D shows a deep foundation 400c. The deep foundation 400c includes a concrete grade beam 440 with pin pile 460 connected to a concrete stem and slab 470 on the top of grade 405. The exterior wall 430 is constructed on the concrete stem and slab 470. Deep foundations 400c are typically used for sites with layers of fill, organic soils, or liquefiable sands that are greater than ten feet below finished grade. Deep foundation 400c elements extend through poor soils and are embedded at least five to ten feet into component soil. The deep foundation 400c may be less common than shallow foundations 400a and post-tensioned slab on grade foundations 400b.

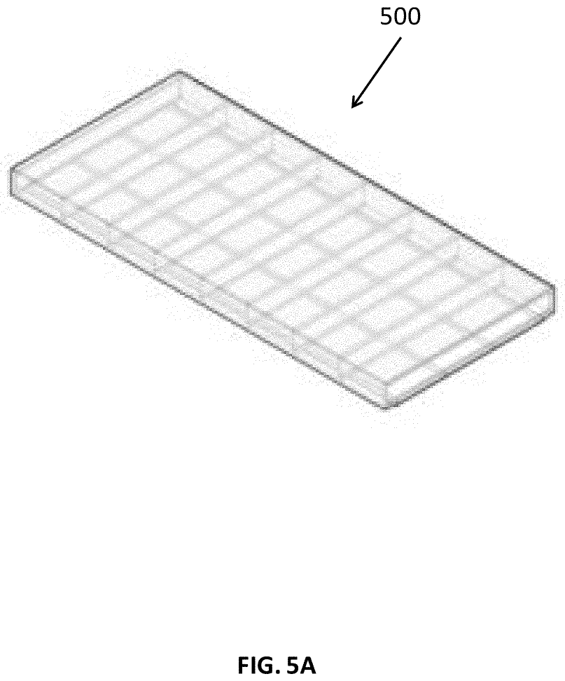

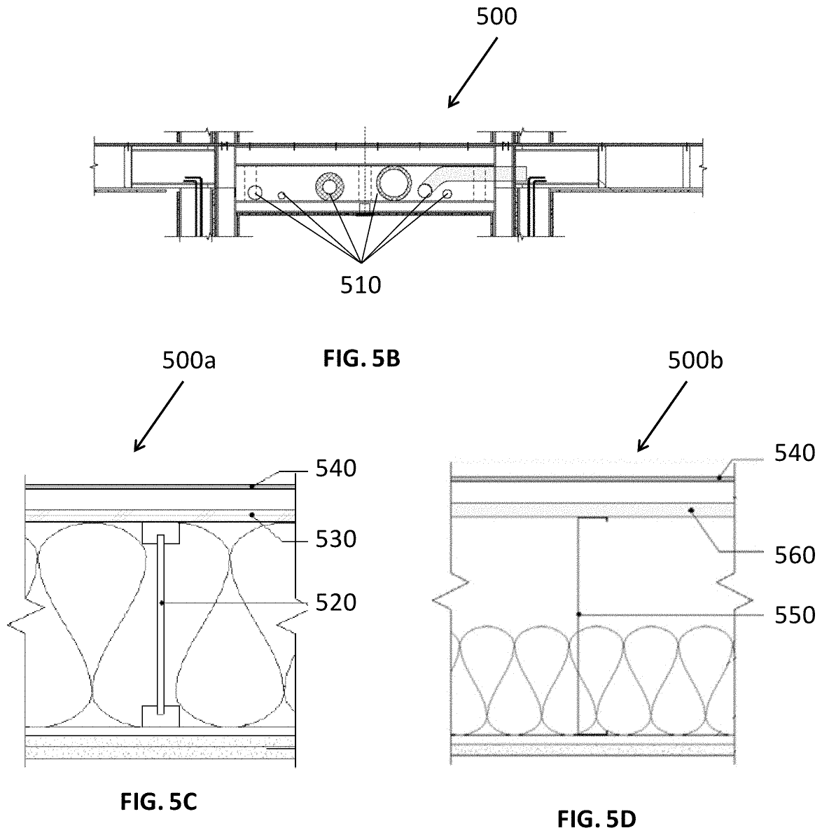

FIG. 5A is a figure of the floor 500 category of assemblies 110. The floor 500 category consists of “standard” and “automated” elements. The floor 500 is established by the unit 120, block 130 choices, and lateral design. The floor panels 500 may be composed of wood and/or cold-formed steel.

FIG. 5B shows a cross-section of a floor panel 500. As shown in FIG. 5B, the floor panel 500 may include mechanical, electrical, and plumbing (MEP) 510 through the floor panel 500. The floor panel 500 may be prefabricated and shipped to the work site. On site, the floor panels 500 can quickly and efficiently be installed and connected to adjacent floor panels 500. The MEP 510 may be installed in the floor panel 500 during prefabrication of the floor panel 500. The MEP 510 is installed when the floor panel 500 is installed. The MEP 510 may be connected to MEP 510 in adjacent floor panels 500. Many different floor panels 500 may be designed and included in the assembly 110 library. The design of the floor panels 500 may include span length and width considerations and different MEP 510 layouts within the floor panels 500. The floor panels 500 may have a length and width that allows the panels 500 to be shipped to the work site via a truck.

FIG. 5C shows a cross-section of a wood floor panel 500a. The wood floor panel 500a may include a wood joist 520, wood structural subflooring 530, and finish floor 540. Wood floor panels 500a allow for acoustic considerations and thermal insulation. However, there may be variability in the wood floor panel 500a.

FIG. 5D shows a cross-section of a cold formed steel (CFS) floor panel 500b. The CFS floor panel may include a CFS joist 550, concrete structural subflooring 560, and finish floor 540. CFS floor panels 500b are more precise than wood floor panels 500a.

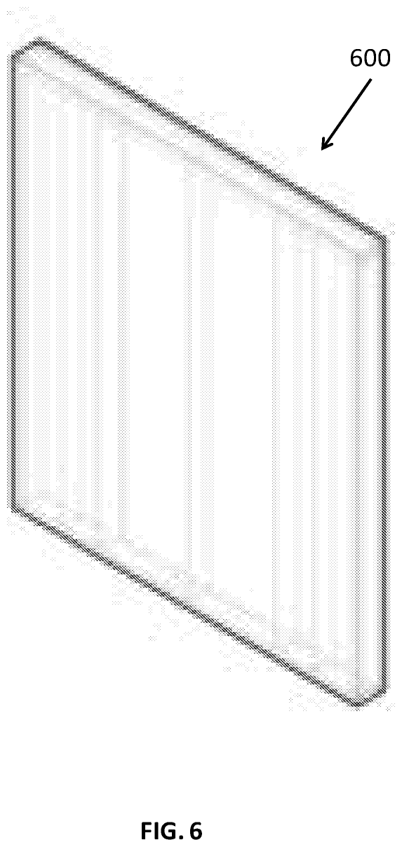

FIG. 6 is a figure of the wall 600 category of assemblies 110. The wall 600 category consists of “standard,” “configurable,” and “automated” elements. The wall panels 600 may be organized in five general categories. The category may include corridor wall panels, demising wall panels, exterior wall panels, interior load-bearing wall panels, and interior non-load-bearing wall panels. These categories are a way of locating the walls 600 to a position within the building 140. The corridor wall is located between a unit 120 and the corridor. The demising wall is located between units 120. The exterior walls include all walls 600 at the perimeter or exterior of the building 140. Interior walls are located within units 120 and define the living space. The interior walls may be load bearing or non-load bearing. The wall panel 600 may include MEP (not shown) running vertically through the wall panel 600. The wall panel 600 may be prefabricated and shipped to the work site. On site, the wall panels 600 can quickly and efficiently be installed and connected to adjacent wall panels 600. The MEP may be installed in the wall panel 600 during prefabrication of the wall panel 600. The MEP is installed when the wall panel 600 is installed. The MEP may be connected to MEP in adjacent wall panels 600. Many different wall panels 600 may be designed and included in the assembly 110 library. The design of the wall panels 600 may include height and width considerations and different MEP layouts within the wall panels 600. The wall panels 600 may have a height and width that allows the panels to be shipped to the work site via a truck.

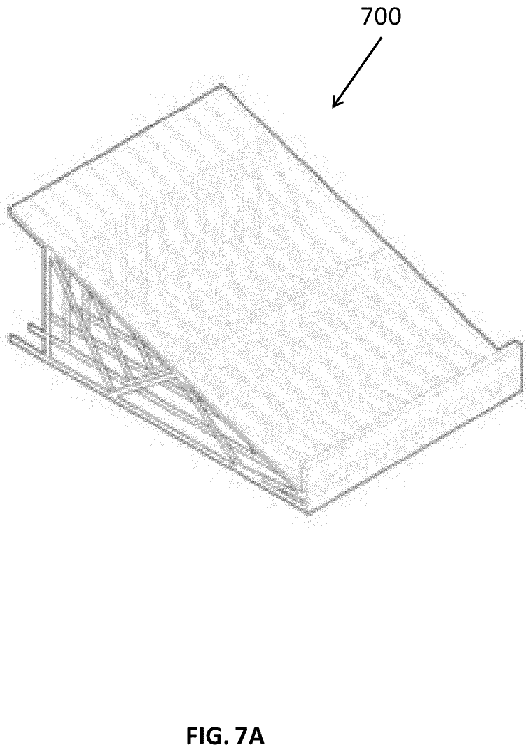

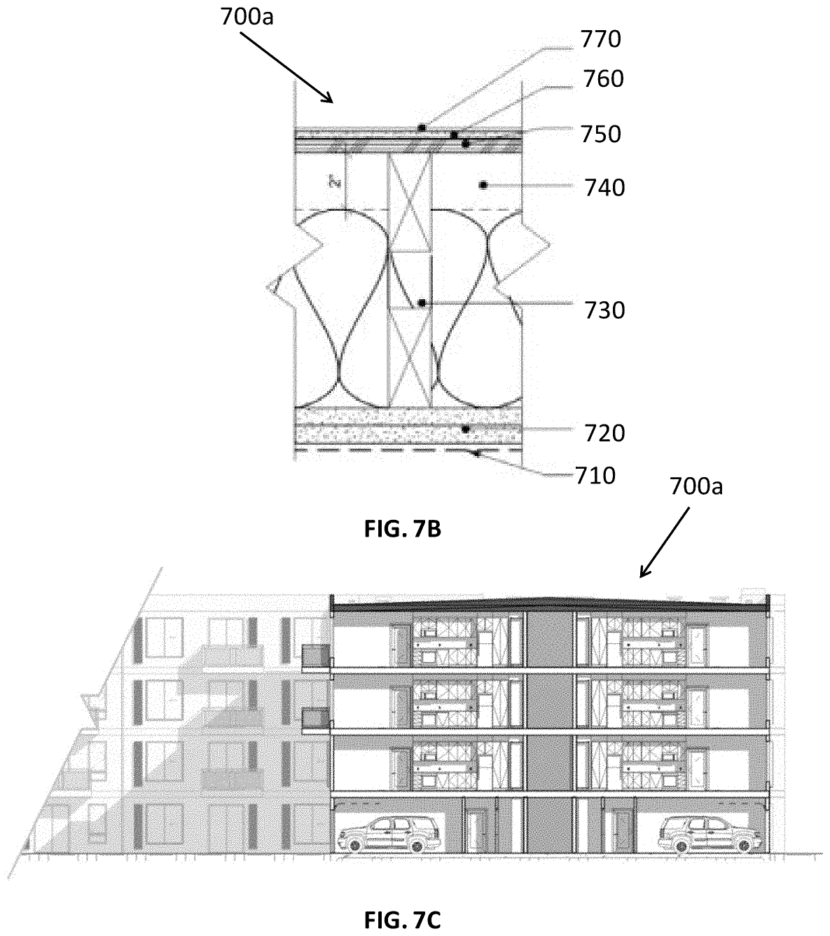

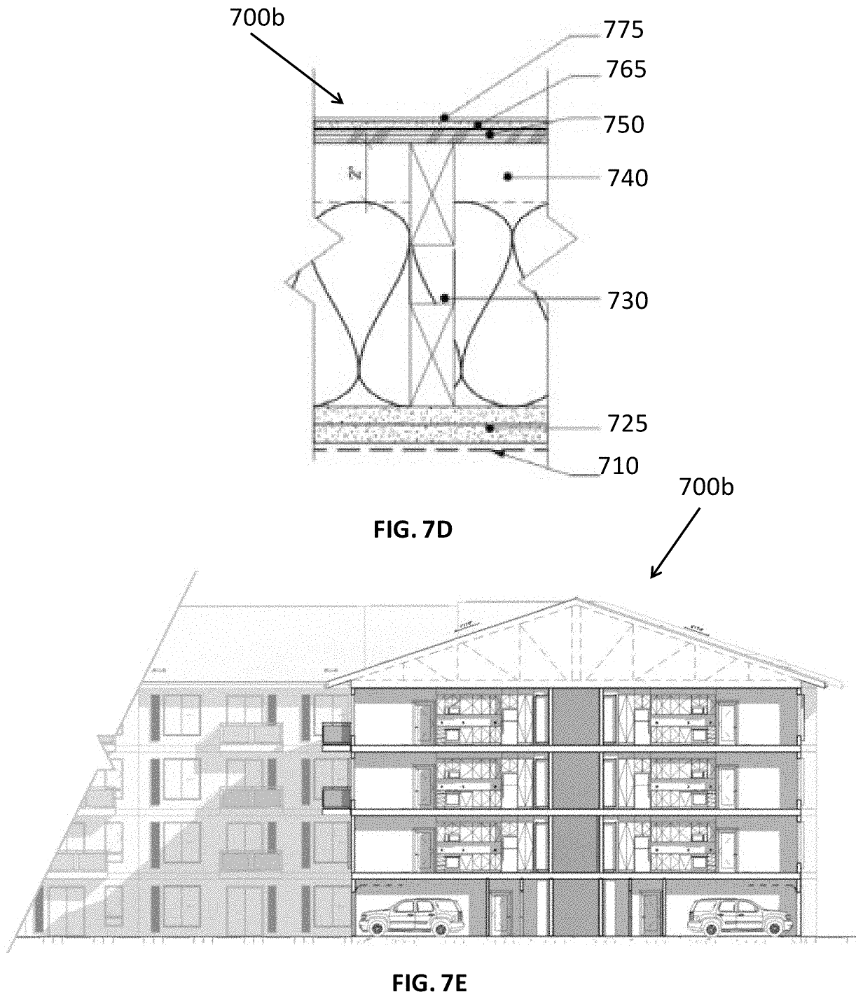

FIG. 7A a figure of the roof 700 category of assemblies 110. The roof 700 category consists of “configurable” elements. The roof 700 is approached at the block 130 or building 140 stage. At least two roofing solutions 700a-b are provided. The roof 700 has at least parapet and eave options available. The first solution 700a includes a low slope roof with parapets. The second solution 700b includes a gable with eaves. In the second option, the slope of the gable may be 4:12. Roof designs may be altered to allow for flexibility for unique, project specific building exteriors.

FIGS. 7B and 7C show the first solution 700a including parapets. This roof solution may include a poly vinyl acetate (PVA) primer vapor retarder 710, at least one layer of ⅝″ type x gypsum wall board (GWB) 720, a wood truss with sloped top chords 730, at least a 2″ air gap between sheathing and insulation for venting 740, a ½″ sheathing panel 750, ⅓″ gypsum coverboard 760, and a single ply thermoplastic polyolefin (TPO) membrane 770. FIGS. 7B and 7C show a low slope TPO roof with parapets. Alternatively, a cost saving option consists of a 4:12 shingled gable behind parapets.

FIGS. 7D and 7E show the second solution 700b including a gable with eaves. This solution may include PVA primer vapor retarder 710, at least one layer of ⅕″ type×GWG 725, wood truss with sloped top chords 730, at least a 2″ air gap between sheathing and installation 740, a ½″ sheathing panel 750, a synthetic roofing underlayment 765, and a three tab composition shingle roofing system 775.

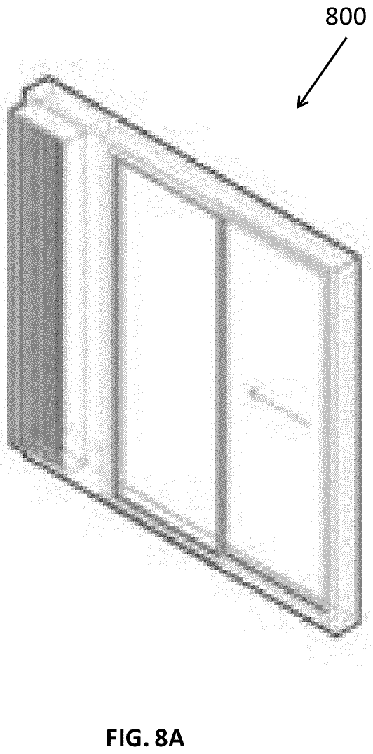

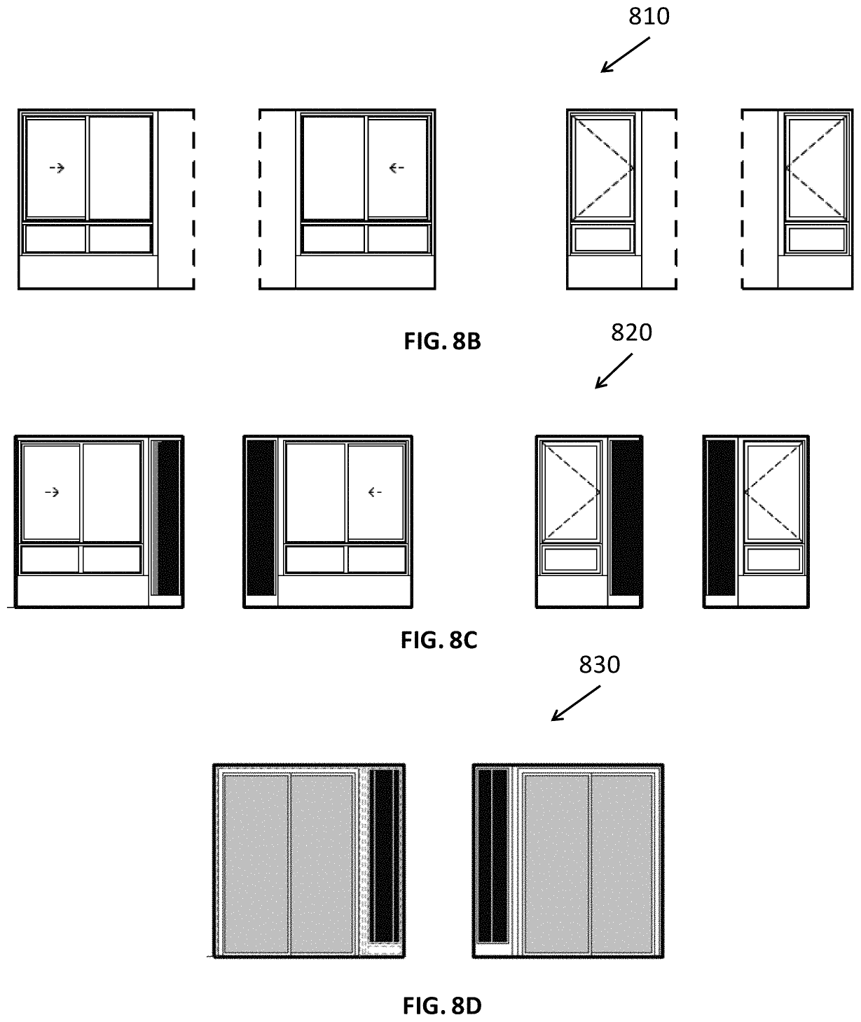

FIG. 8A is a figure of the fenestration 800 category of assemblies 110. The fenestration 800 category consists of “configurable” elements. The fenestrations 800 have a fixed set of options available. The fenestrations 800 may be designed for an 8′×8′ zone or 8′×5′ zone for variable window expressions. A fixed fenestration 800 catalog of at least two basic windows and one sliding door configured in multiple arrangements allows for flexible facade expression across projects while keeping product variability to a minimum. The designated zones for window expressions may also allow for an air conditioner. FIG. 8B shows exemplary window configurations 810. FIG. 8C show exemplary window and air condition configurations 820. FIG. 8D show exemplary sliding door and air condition configurations 830. The wall panels 600 may be prefabricated with the fenestrations 800 installed.

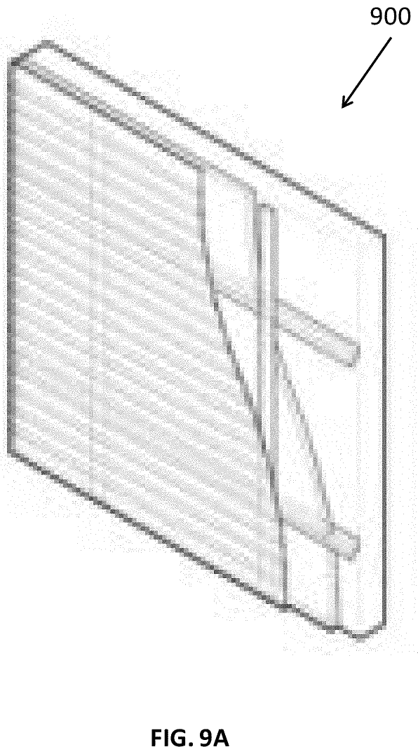

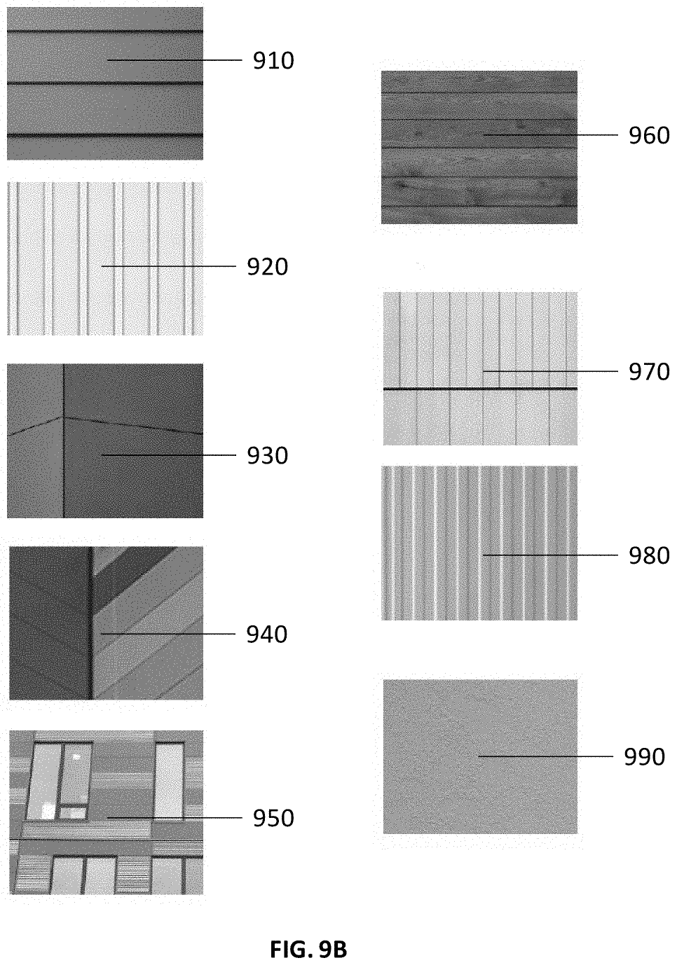

FIG. 9A is a figure of the enclosure 900 category of assemblies 110. The enclosure 900 category consists of “custom” elements. The enclosures 900 rely on an exterior finish matrix. The enclosure 900 category encompasses all exterior cladding from the exterior face of the sheathing and outward. Project specific facades may be chosen from a catalog of pre-approved exterior finish options. The cladding may be organized into four categories including solid finish fiber cement cladding, stucco, metal appearance cladding, and wood appearance cladding. These categories may be further organized into tiers based on the cost of material. For example tier 1 may be the cheapest while tier 3 may be the most expensive. FIG. 9B depicts example enclosures 900. FIG. 9B shows lap sliding 910, board and batten 920, large format panels 930, horizontal panels 940, metal appearance 950, wood or thermally modified wood 960, a first option for metal panel 970, a second option for metal panel 980, and stucco 990.

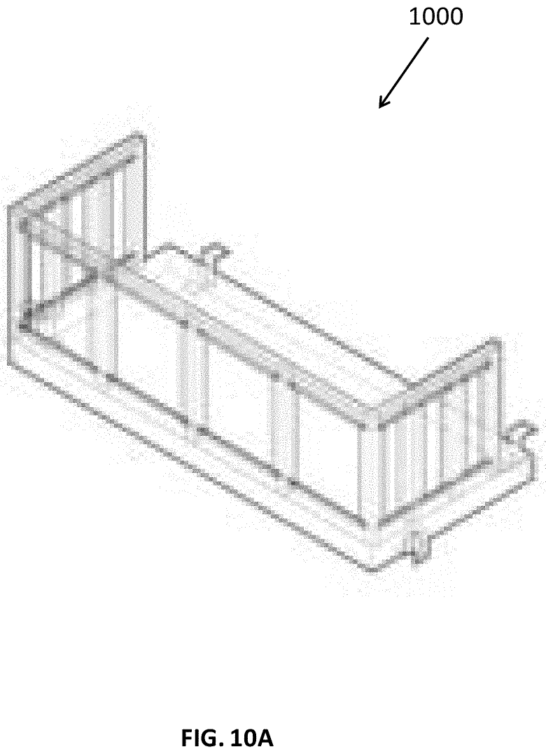

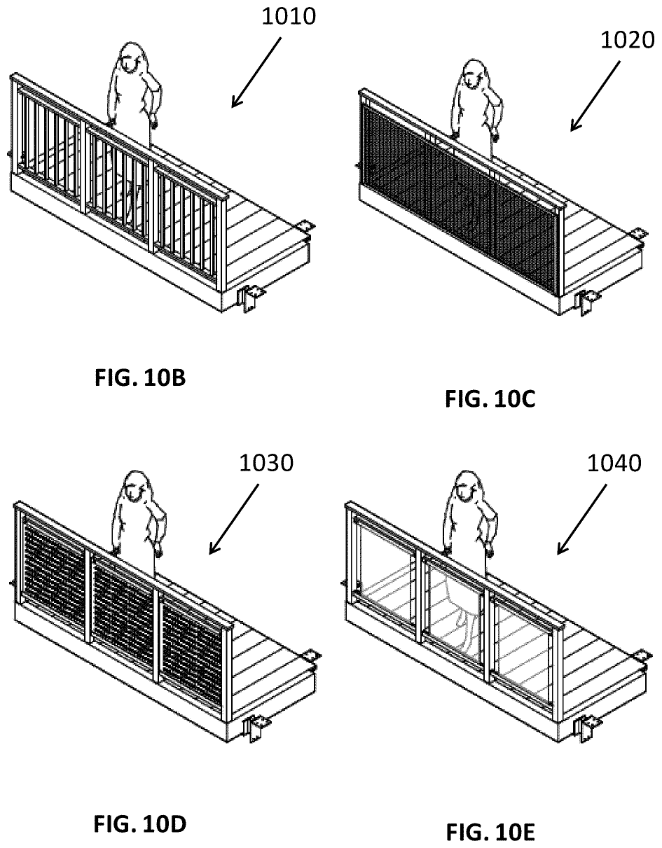

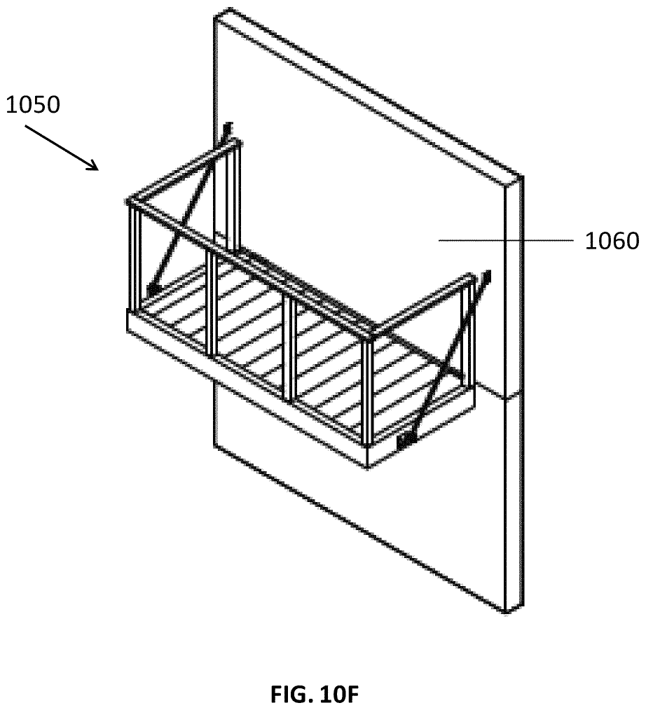

FIG. 10A is a figure of the exterior accessory 1000 category of assemblies 110. The exterior accessory 1000 category consists of “configurable” elements. The exterior accessories 1000 have a fixed set of options available. The exterior accessory 1000 category captures all exterior balcony, awning, screen, downspout, and lighting solutions. The projects allow for configurable balcony design through a limited catalog of sizes, railing types, and finishes. Different balcony options may be configured from a number of color options, decking options, and railing options. For example, the color options may include white, gray, black, or a custom color. Moreover, the colors may be a gloss or matte finish. For ease of manufacturing and coordination, standard color options may be used to match standard window and doors. Decking options may include diamond plate aluminum decking or extruded aluminum decking. Aluminum decking provides longevity, reduces weight, and improves strength of the balcony structure. Aluminum planks can span distances of up to 5′ without additional structure while providing superior weather resistance. FIGS. 10B-10E show example railing options. FIG. 10B shows a picket railing option 1010. FIG. 10C shows a welded mesh infill railing option 1020. FIG. 10D shows a perforated infill railing 1030. FIG. 10E shows a glass infill railing option 1040. A limited palette of finish railing options for balcony systems is intended to drive standardization of major visible elements. These finishes drive a consistent aesthetic between buildings and project sites. Moreover a limited size offering of the balcony reinforces product standardization and simplifies attachment coordination. FIG. 10F shows a balcony 1050 attached to the exterior of a wall 1060.

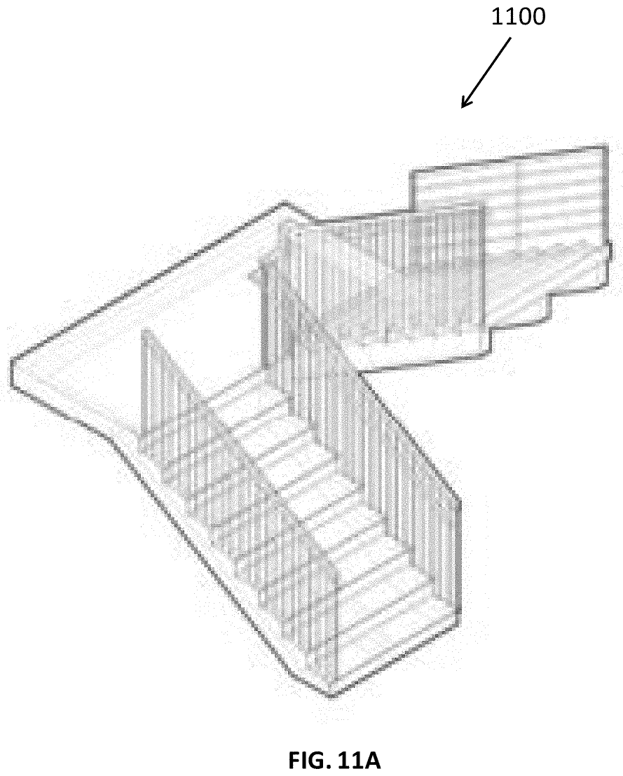

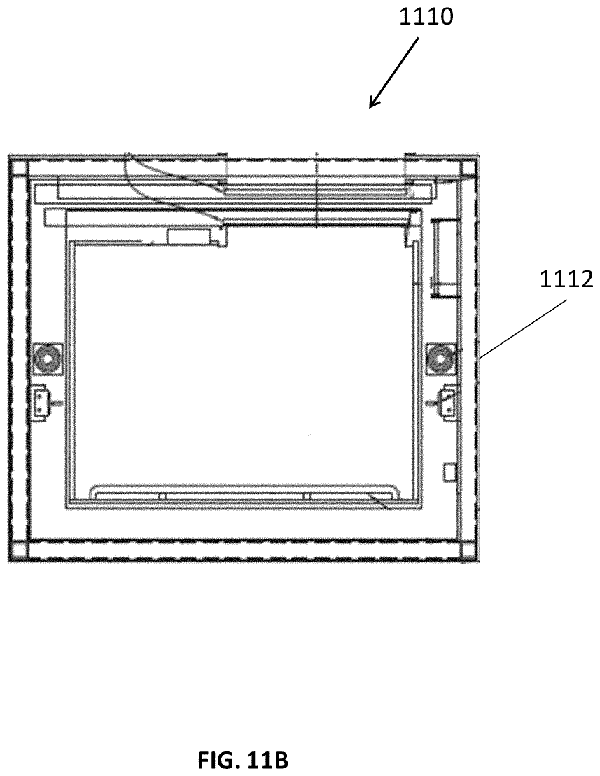

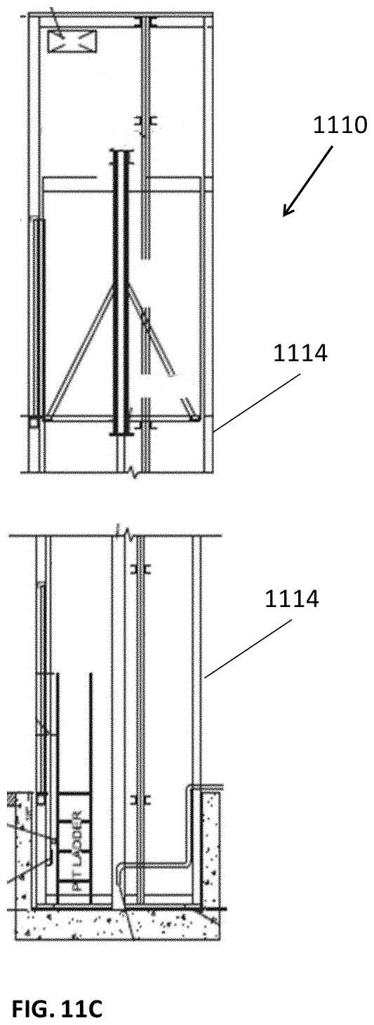

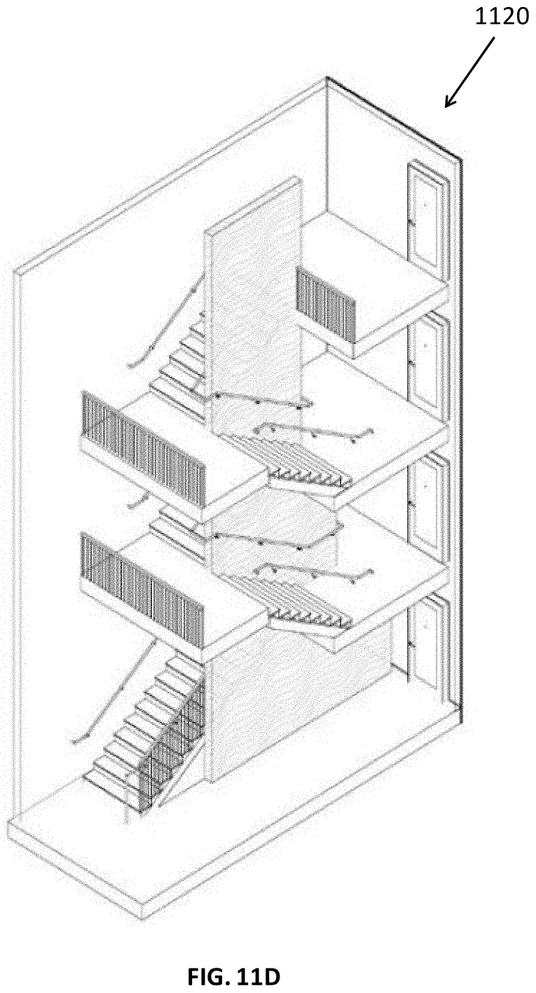

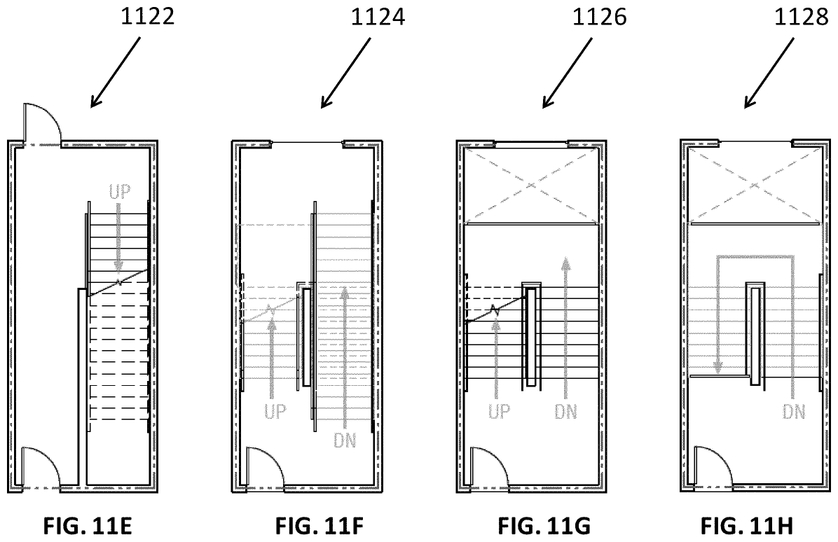

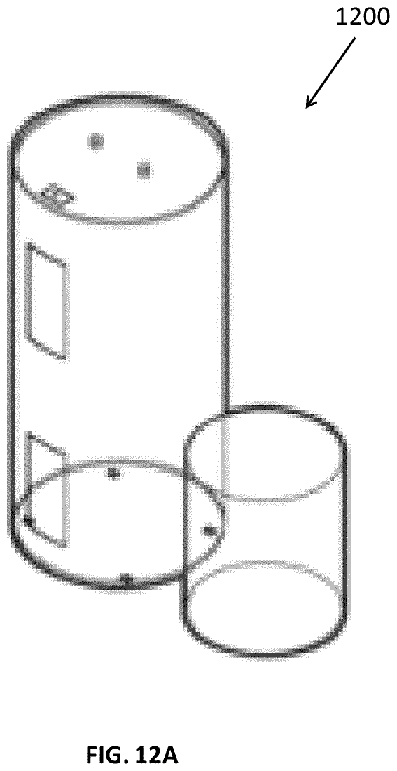

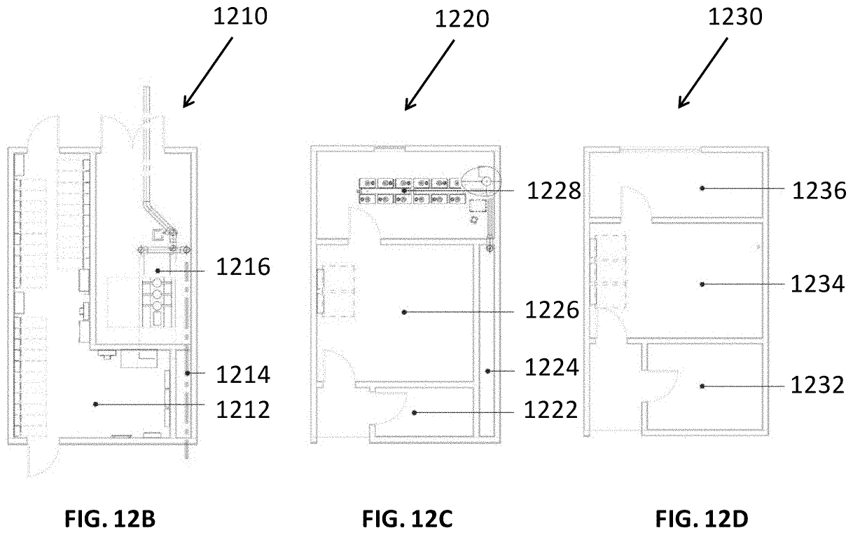

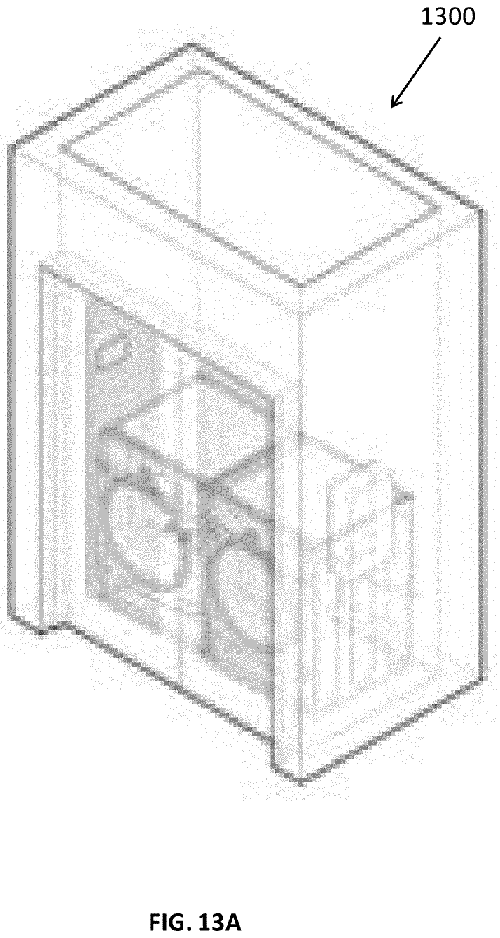

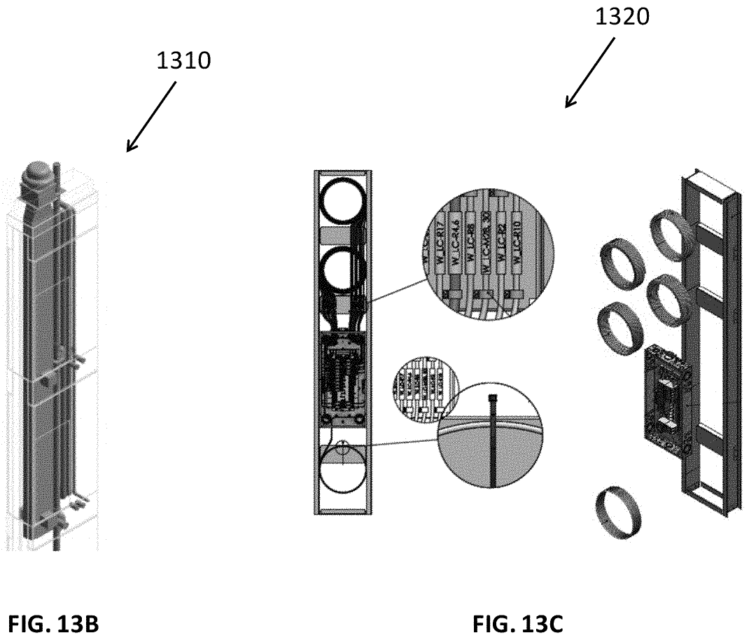

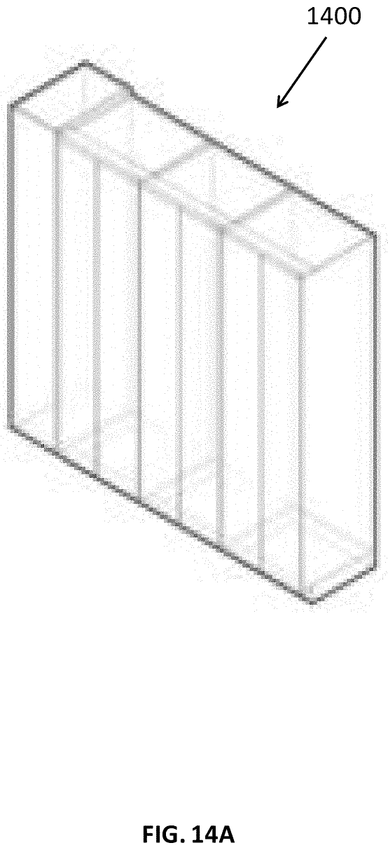

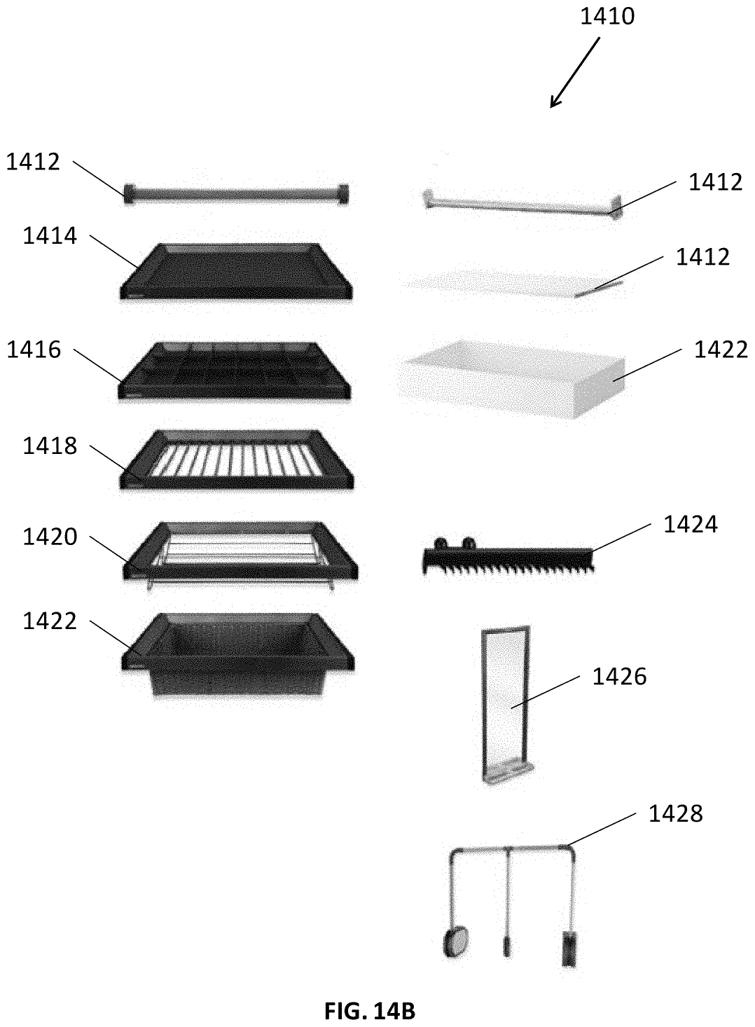

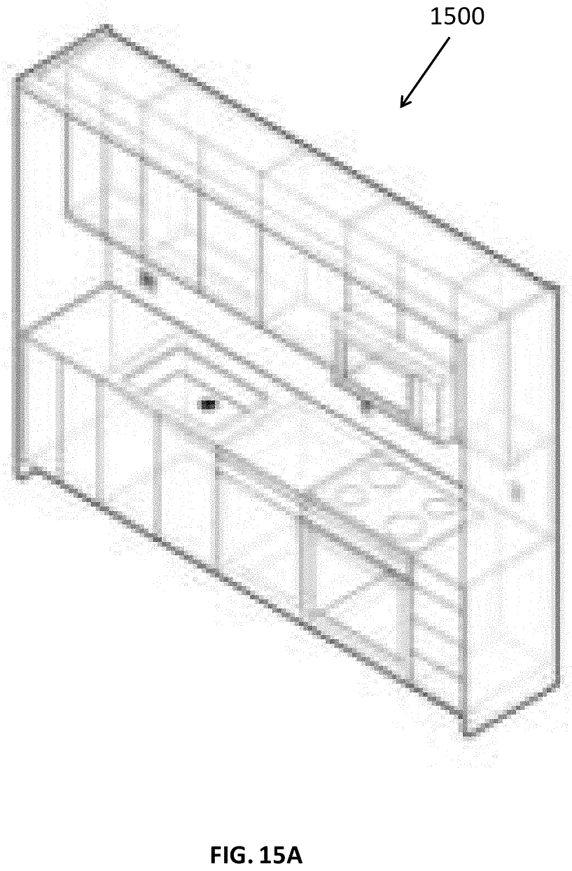

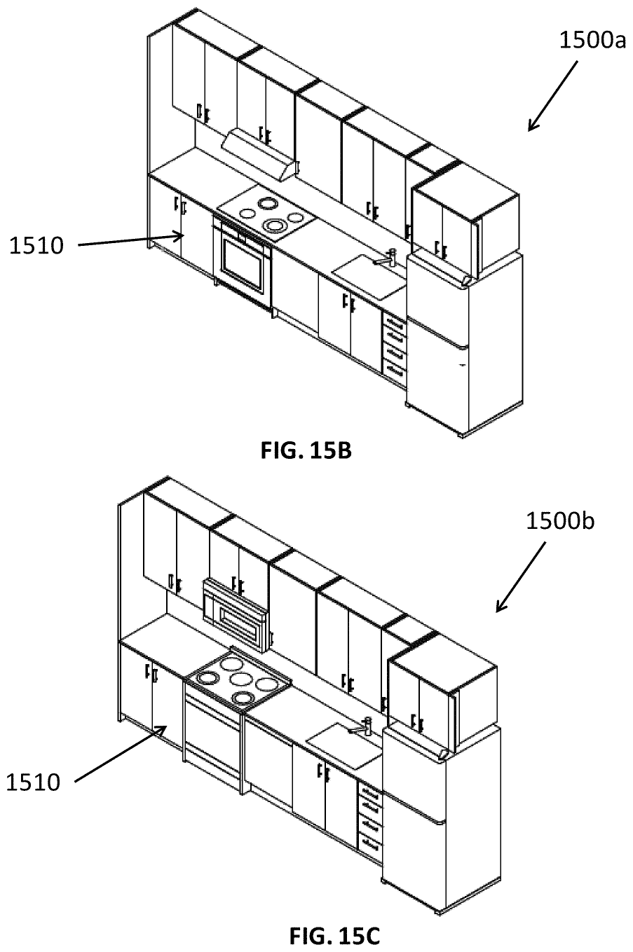

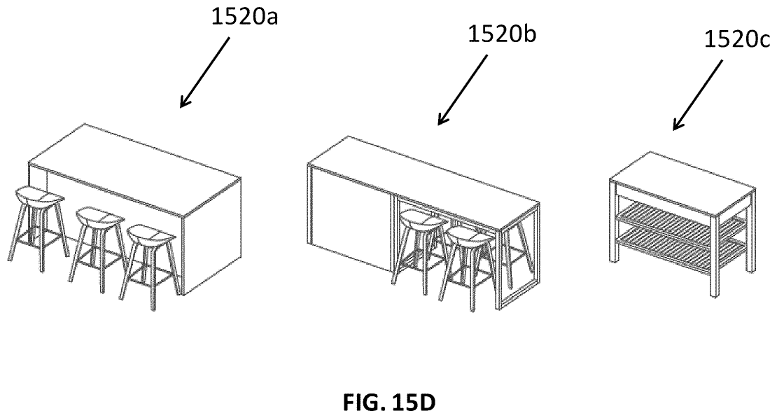

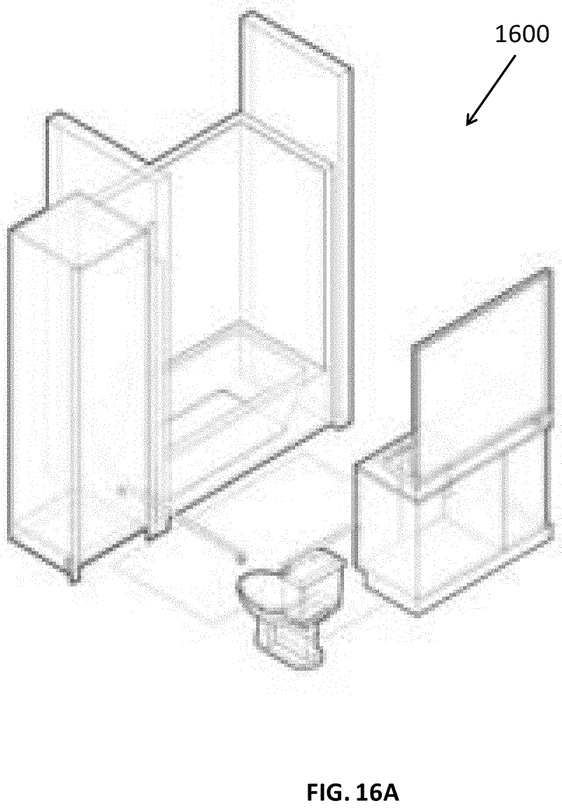

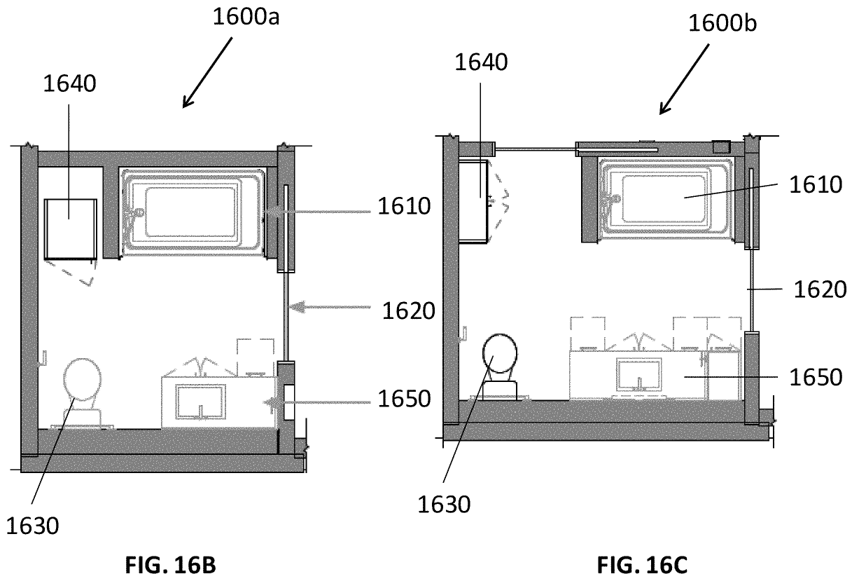

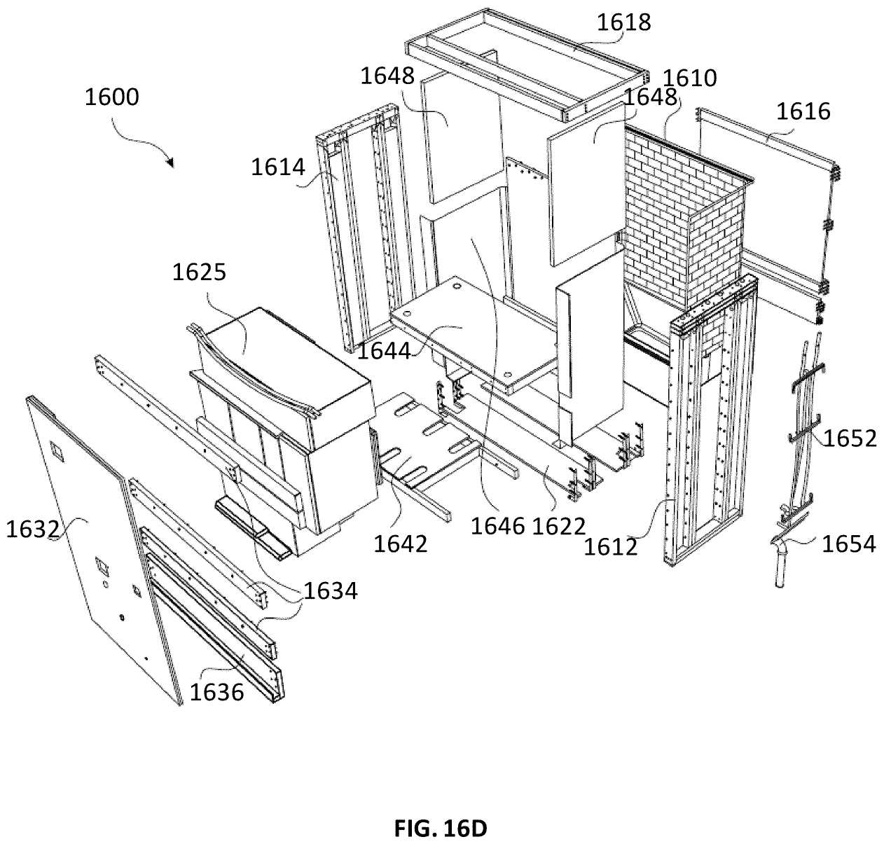

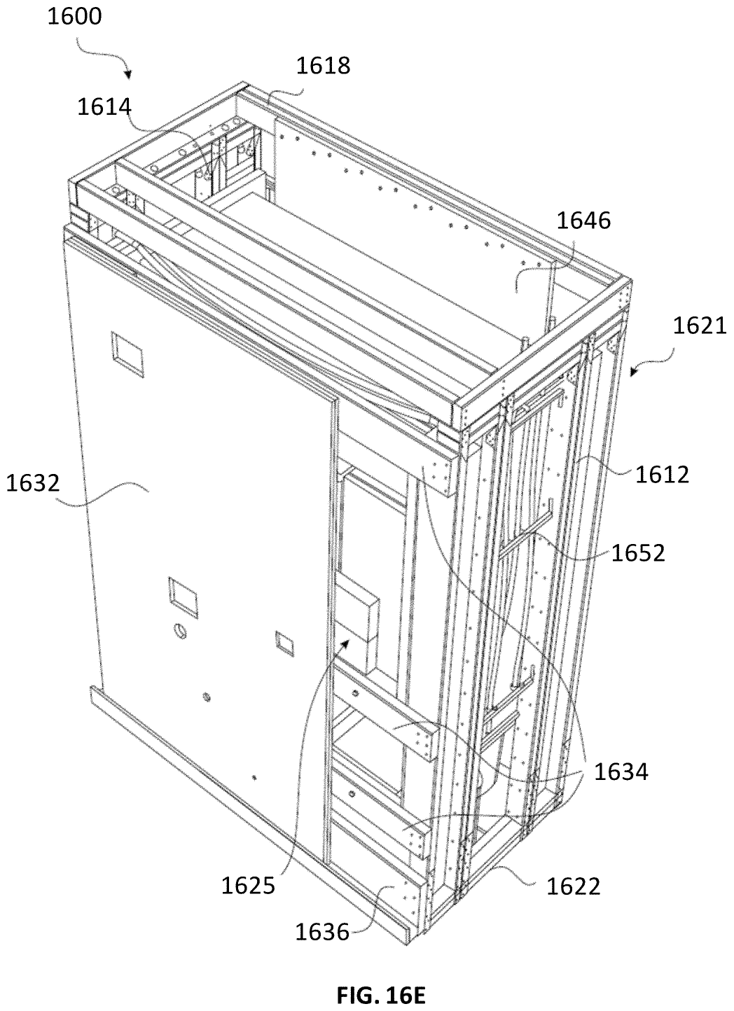

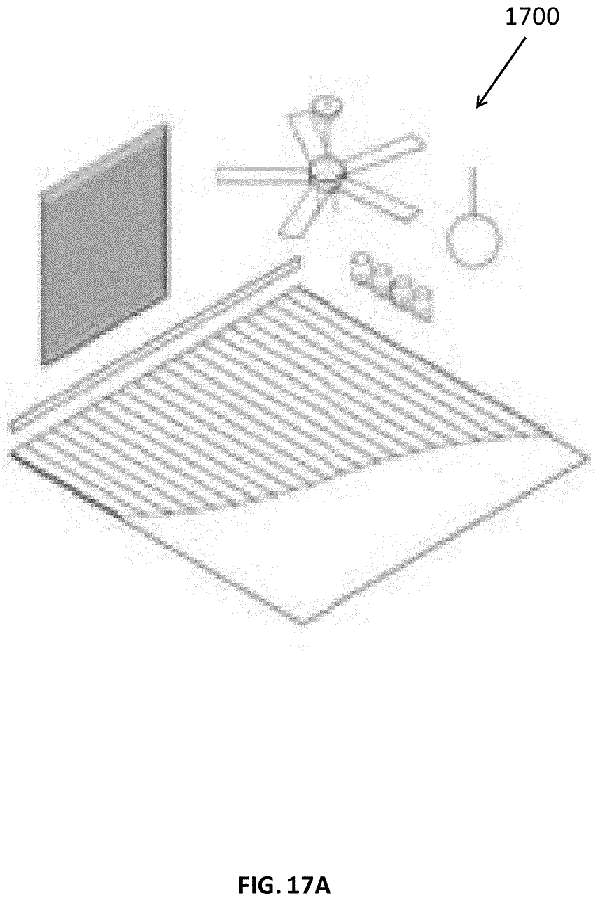

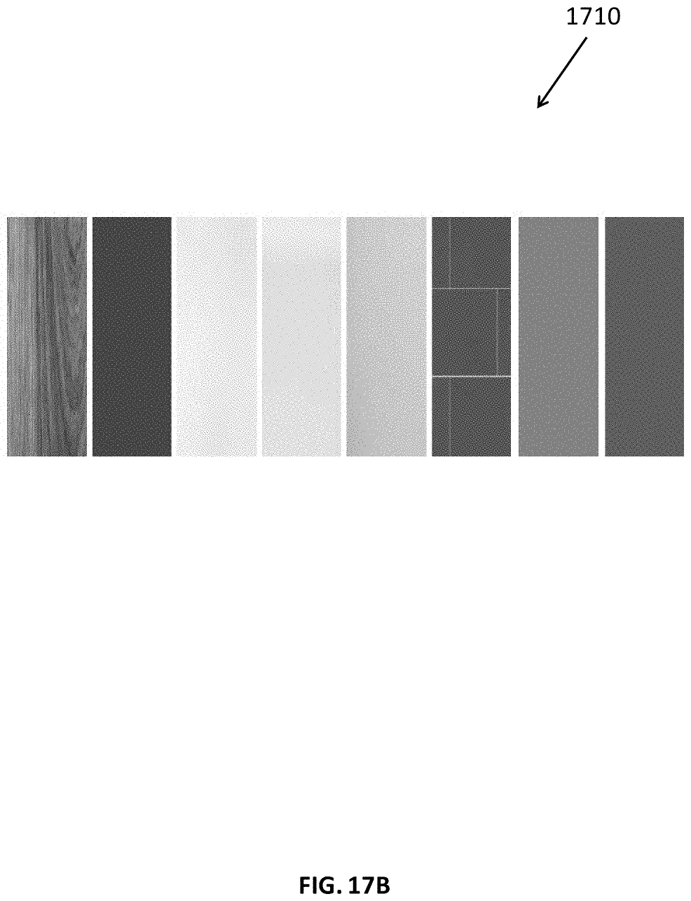

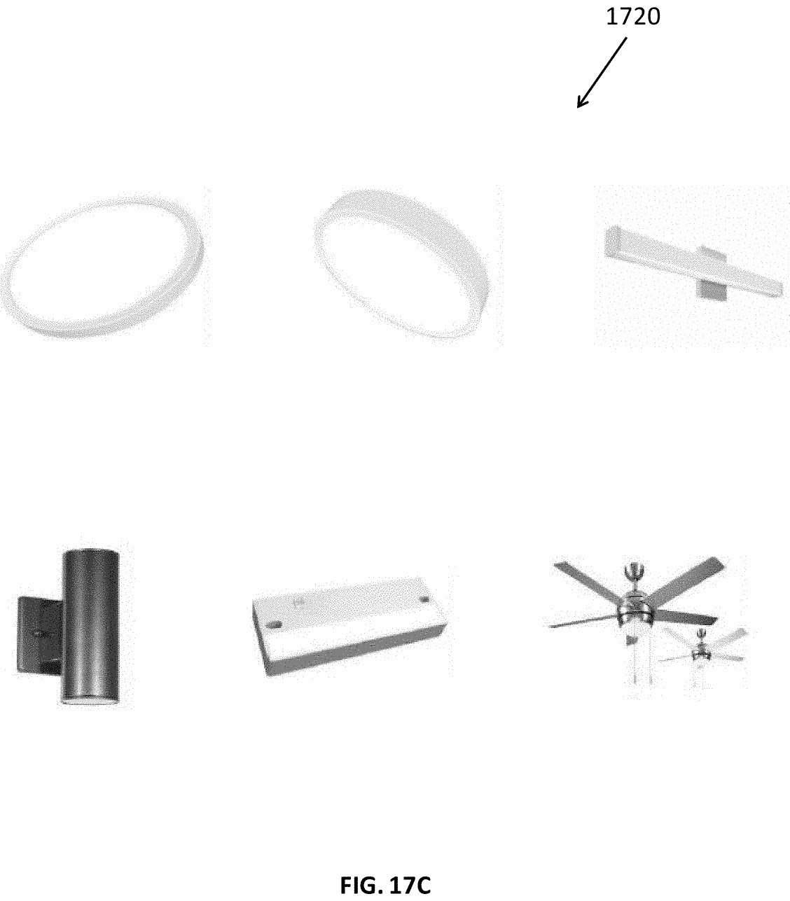

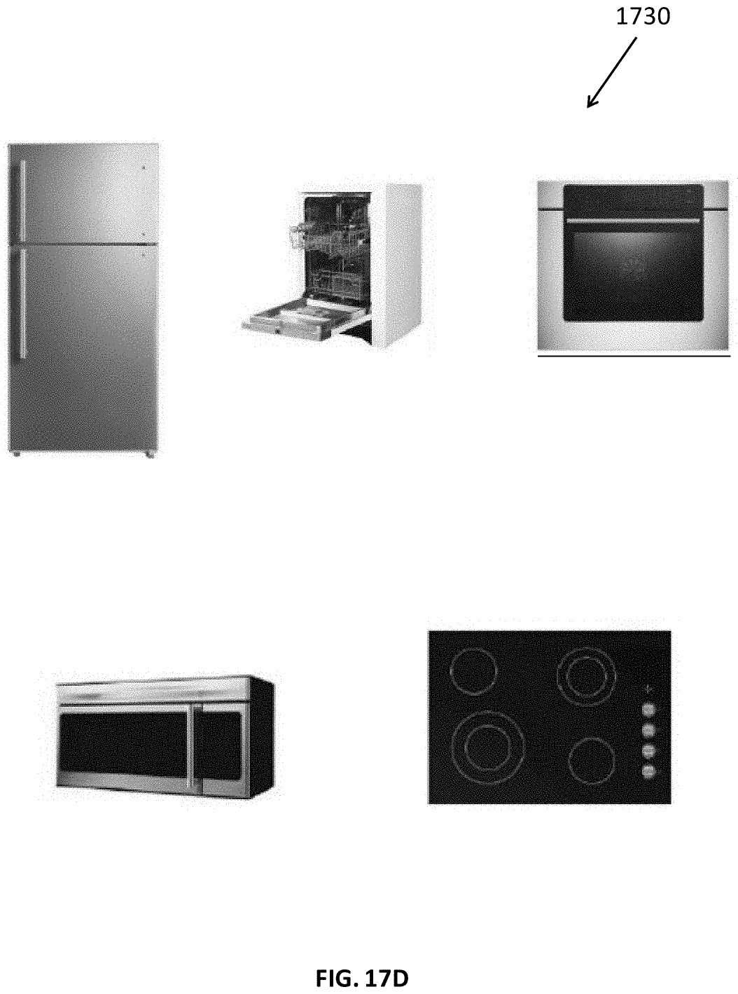

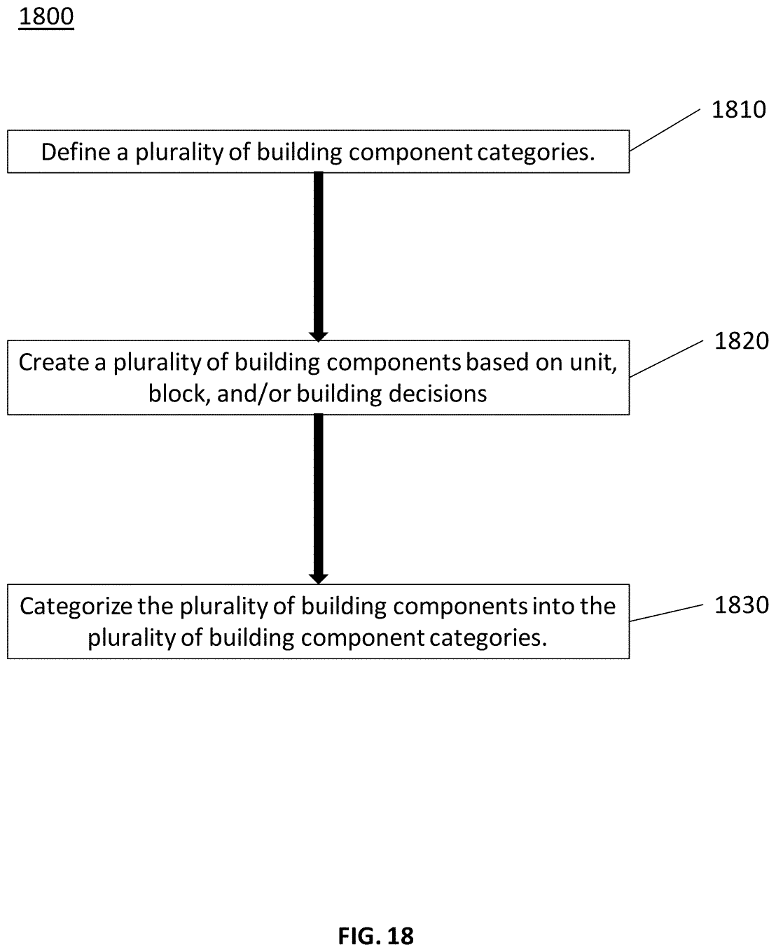

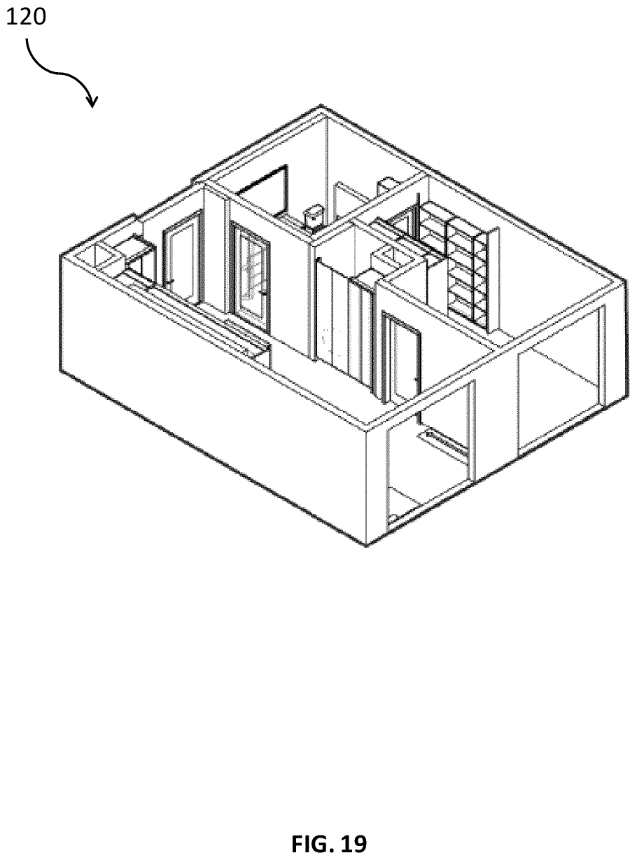

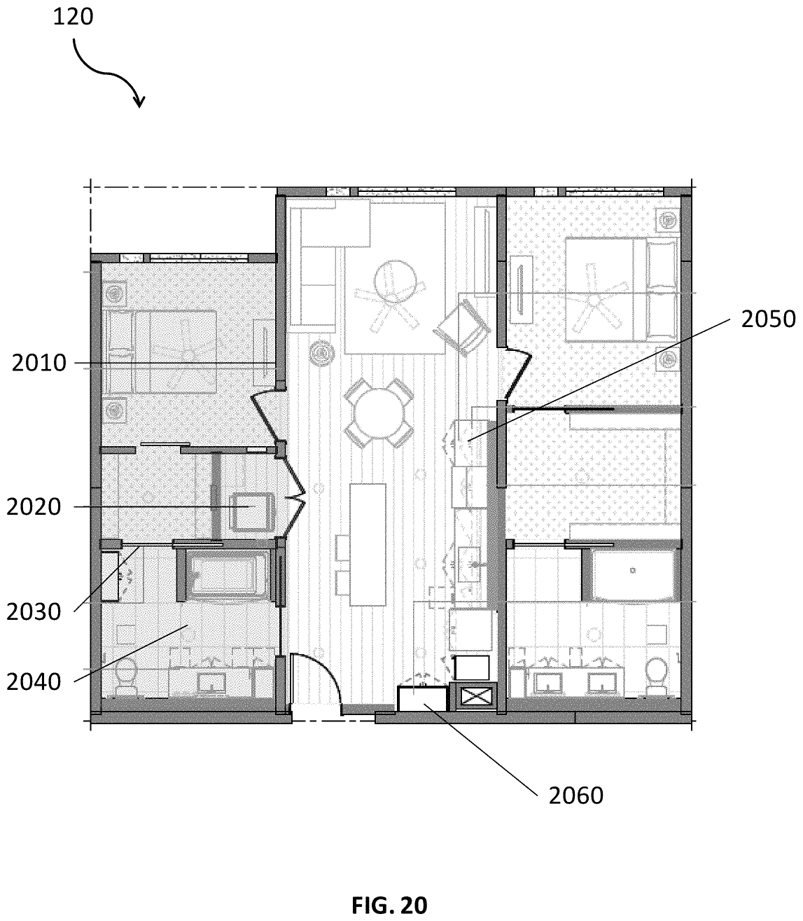

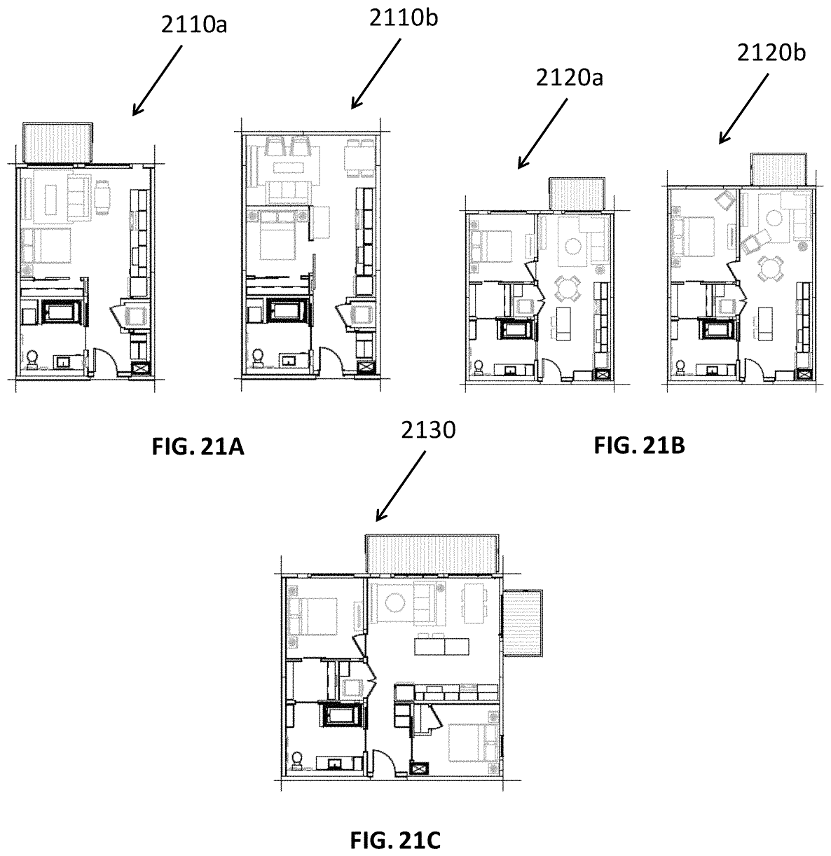

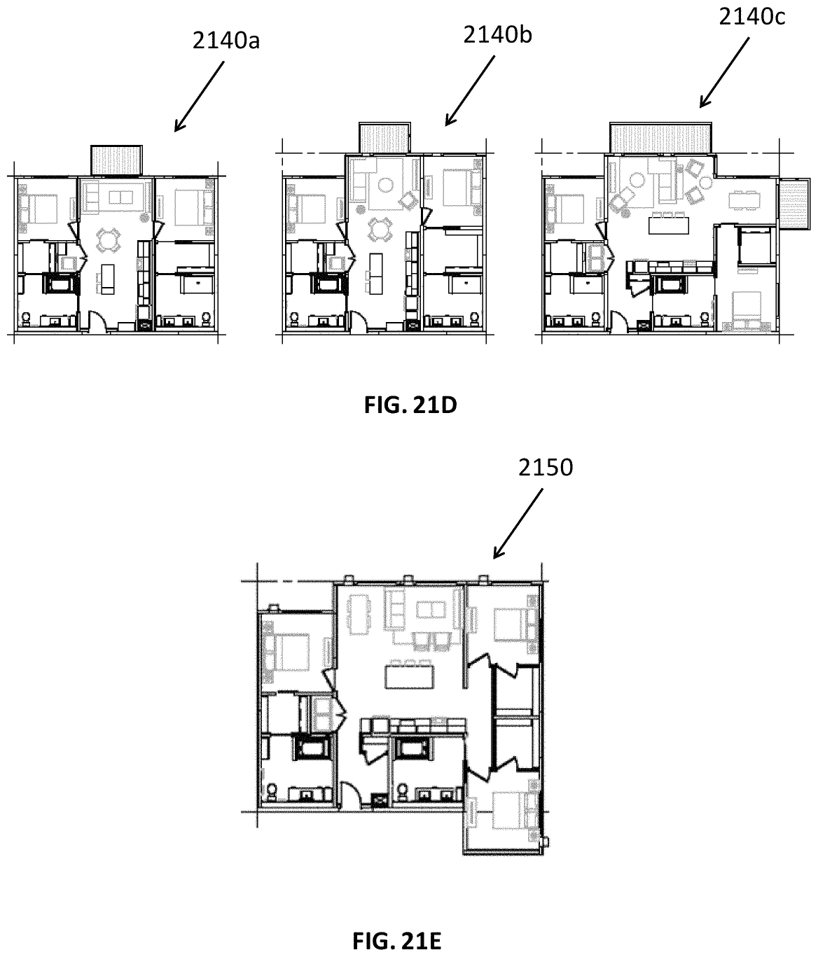

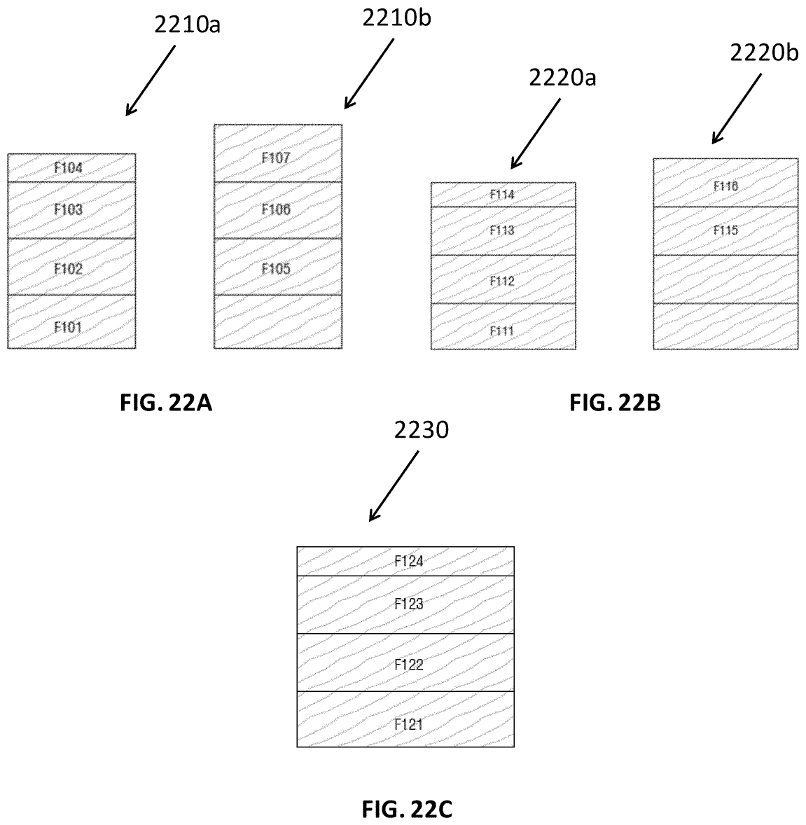

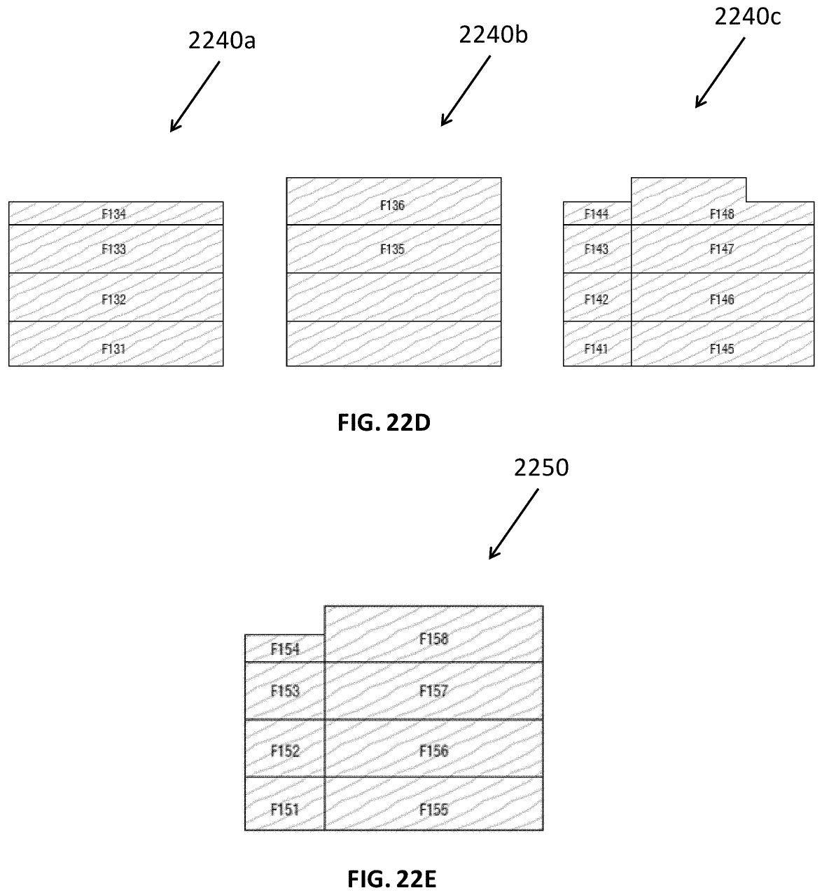

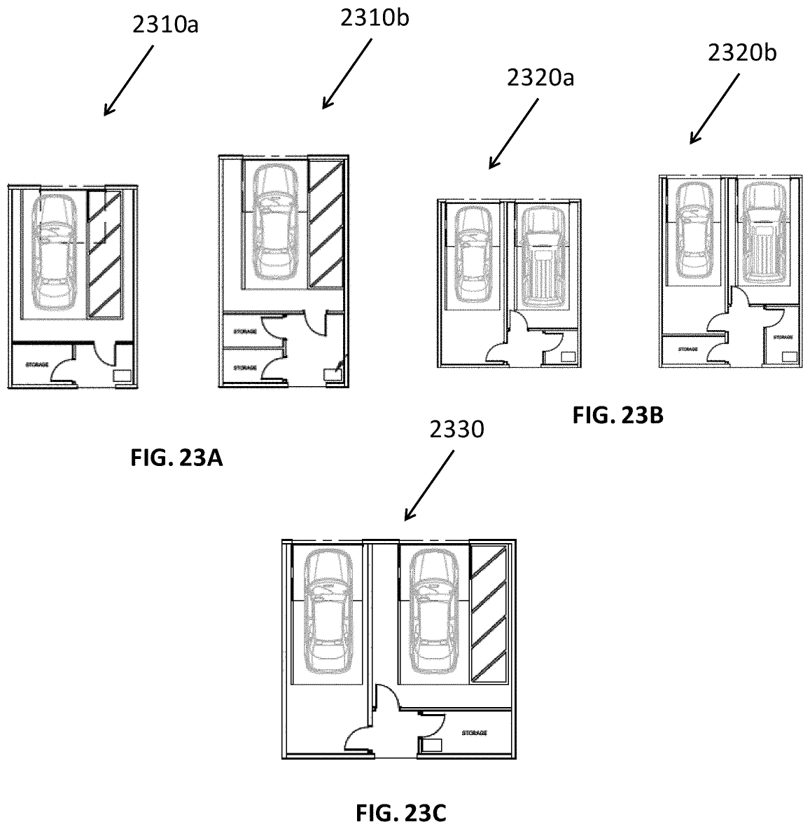

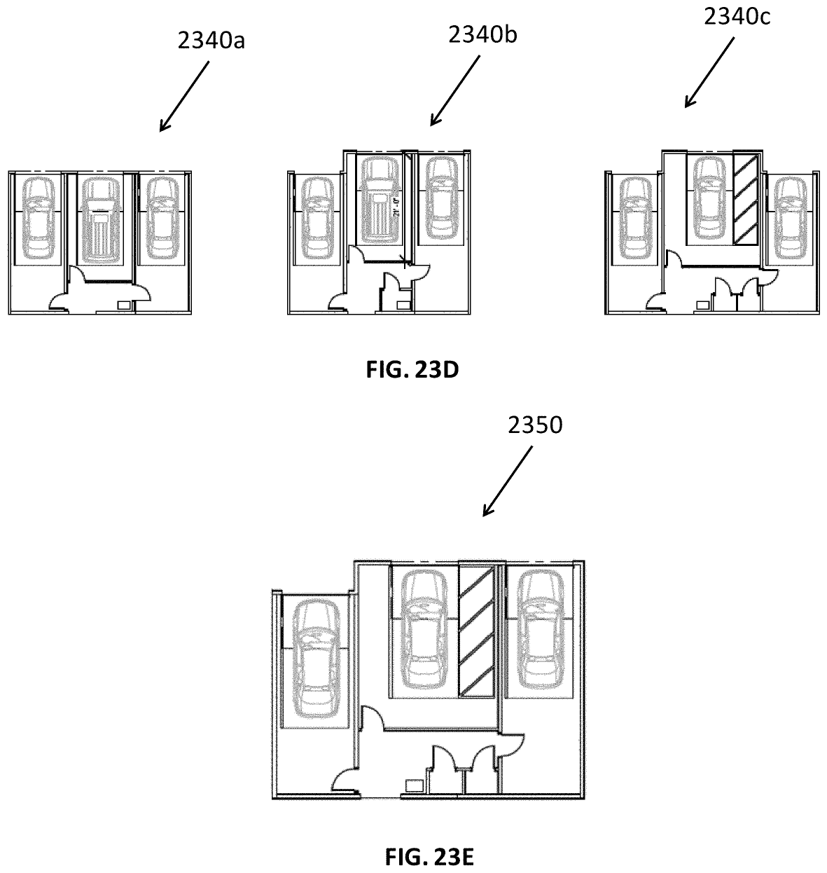

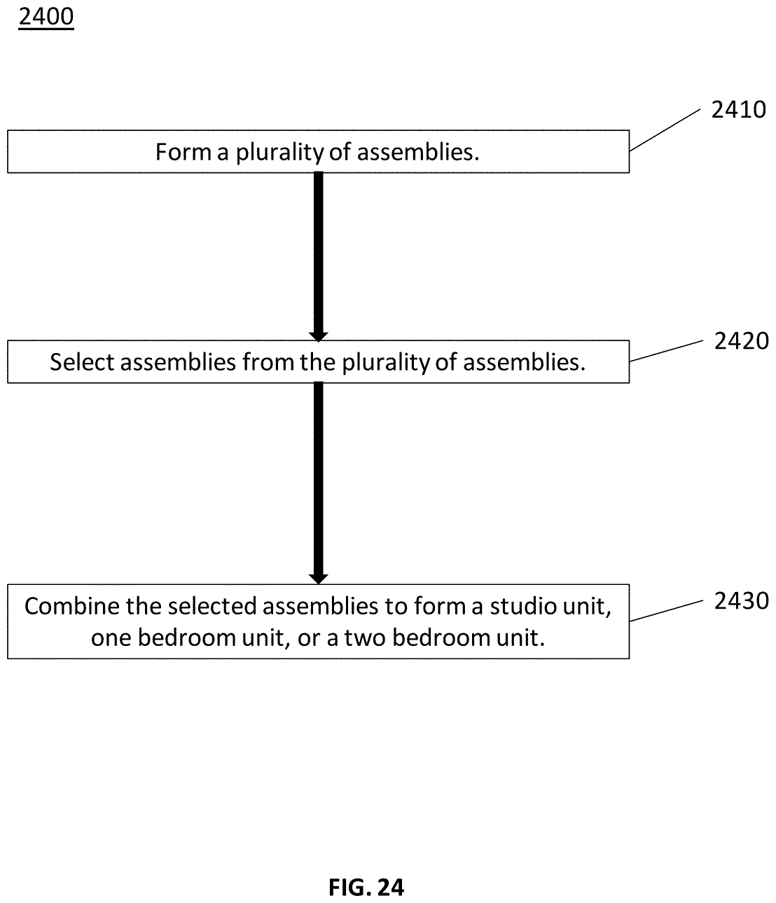

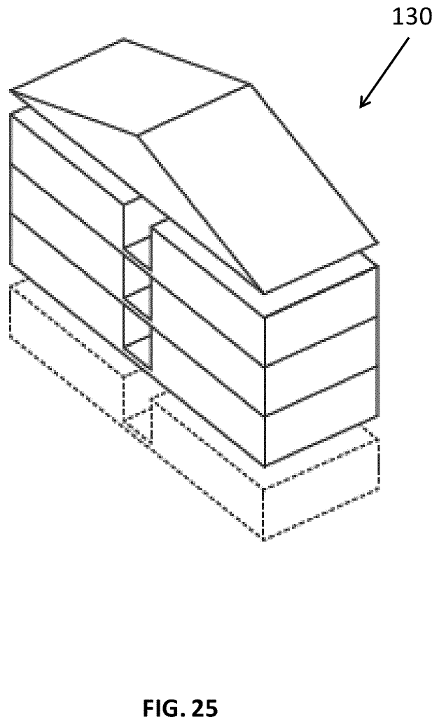

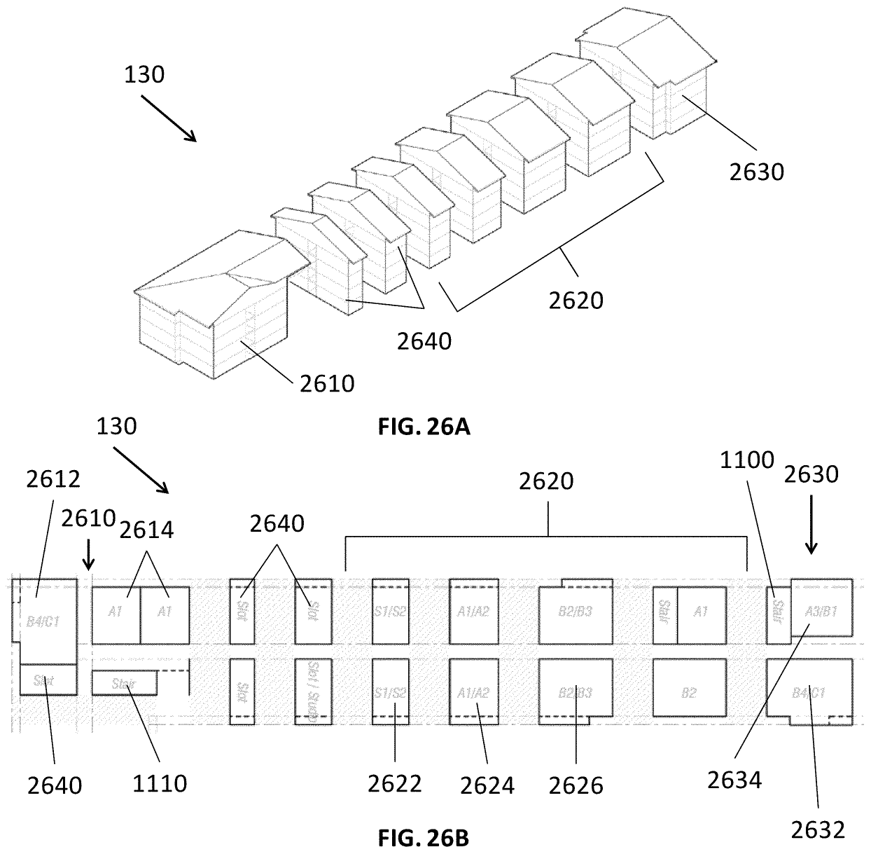

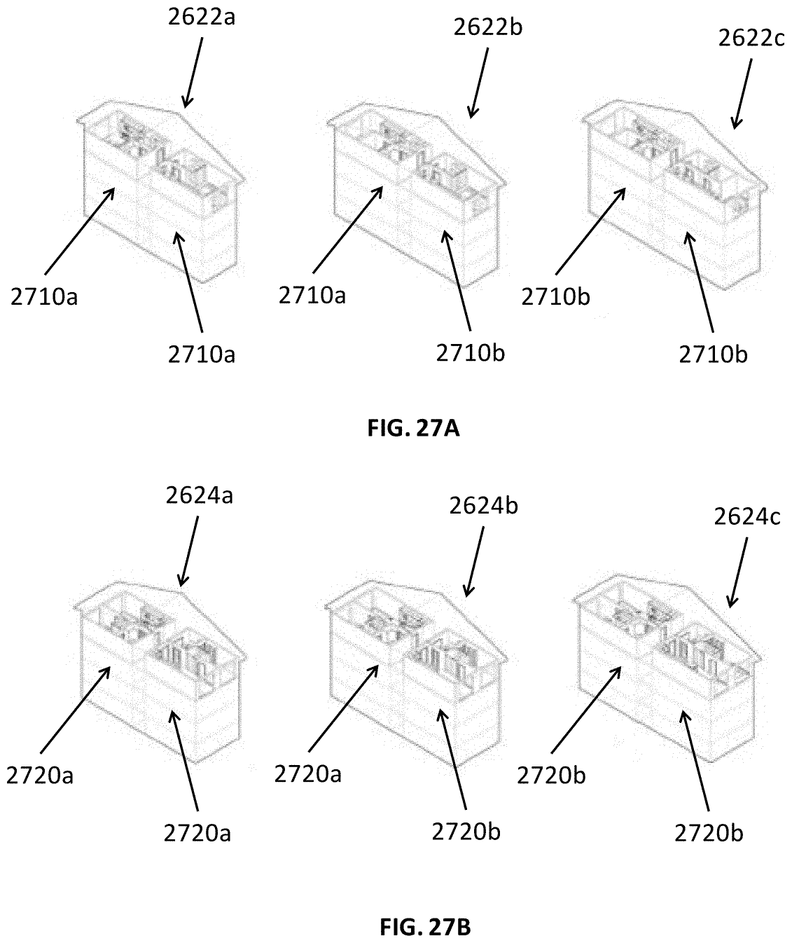

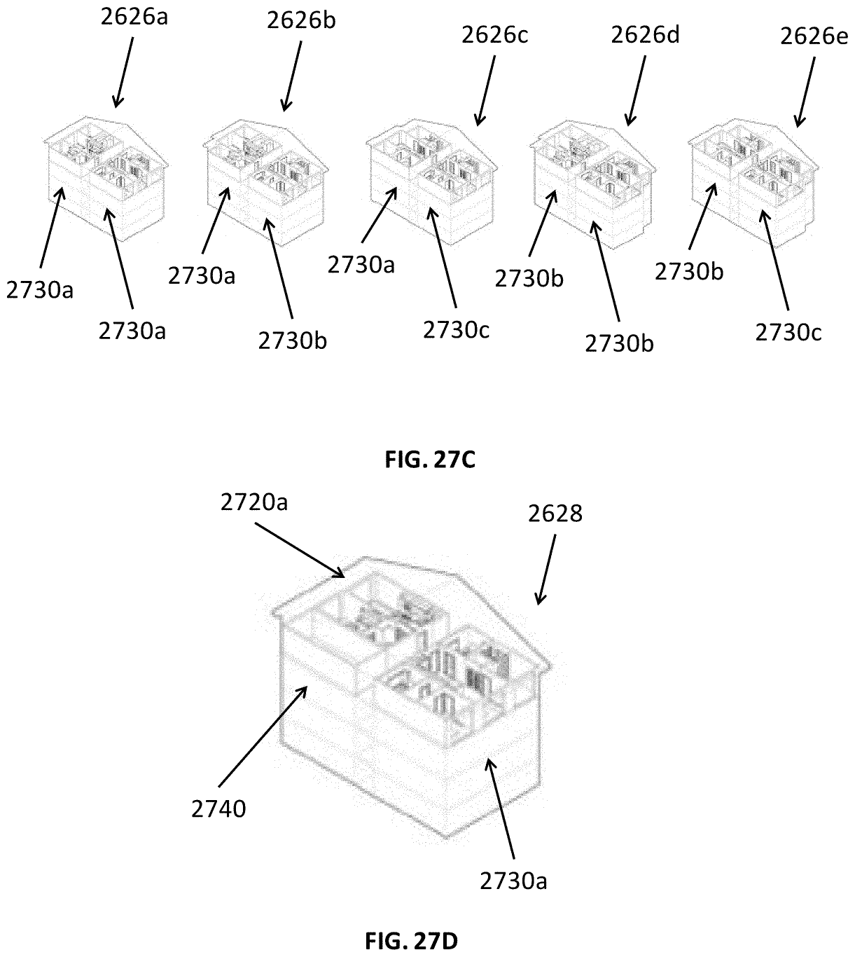

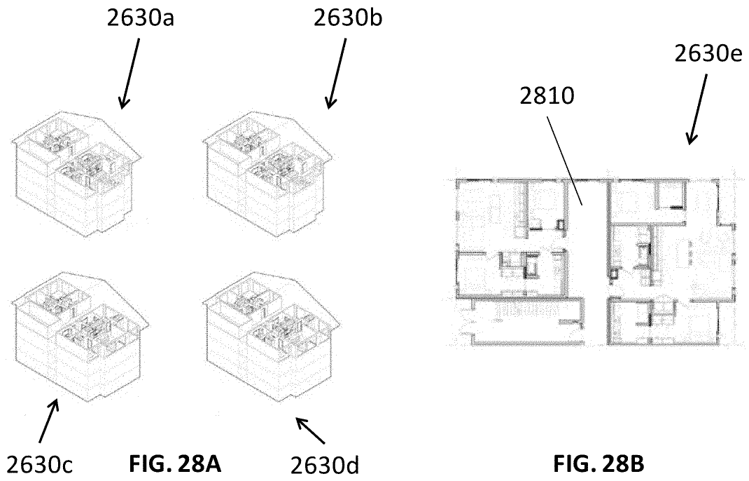

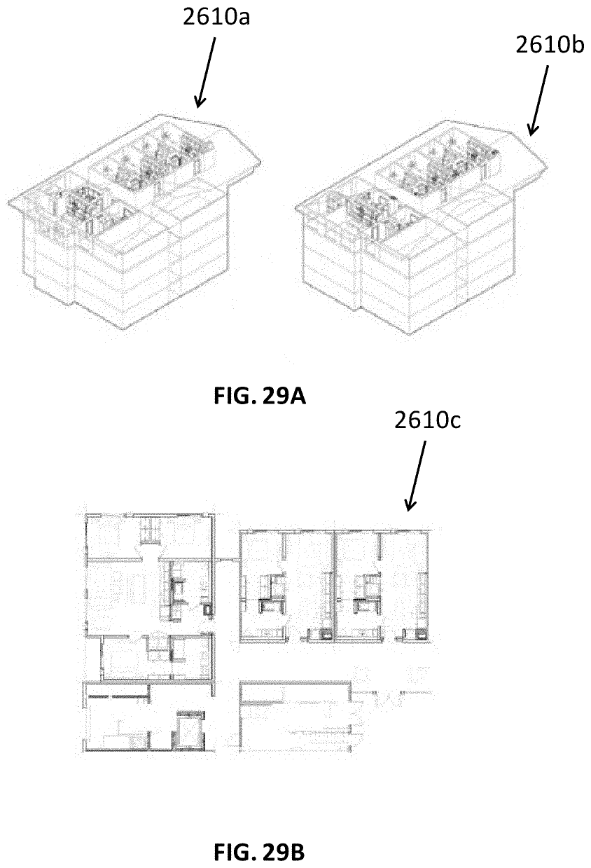

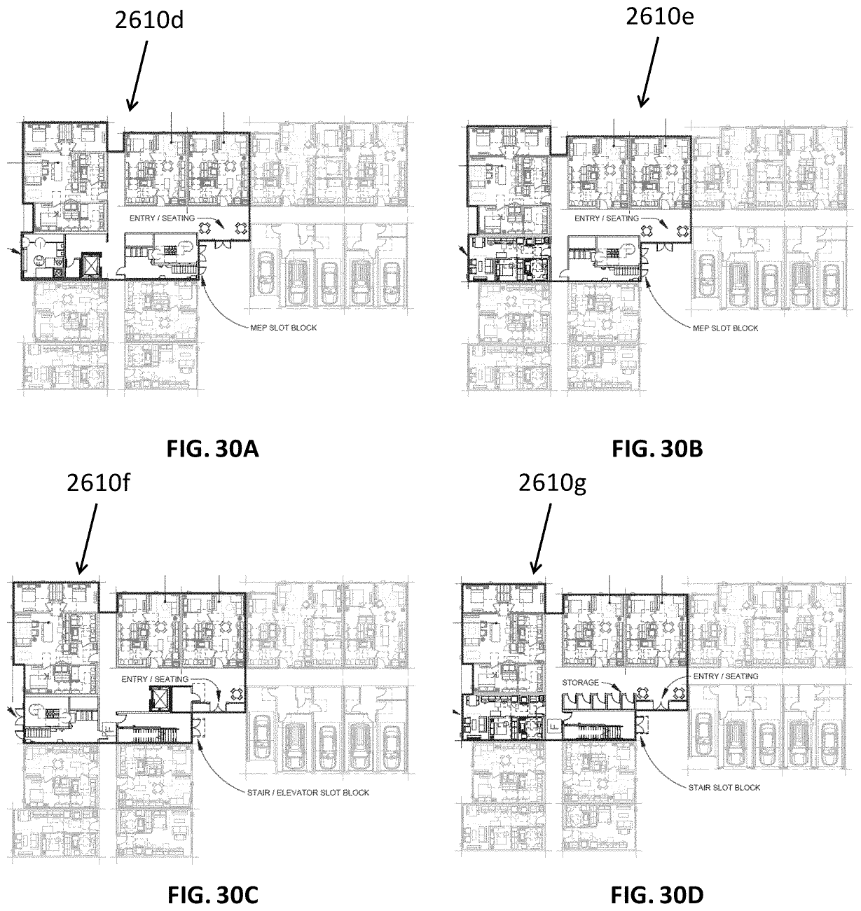

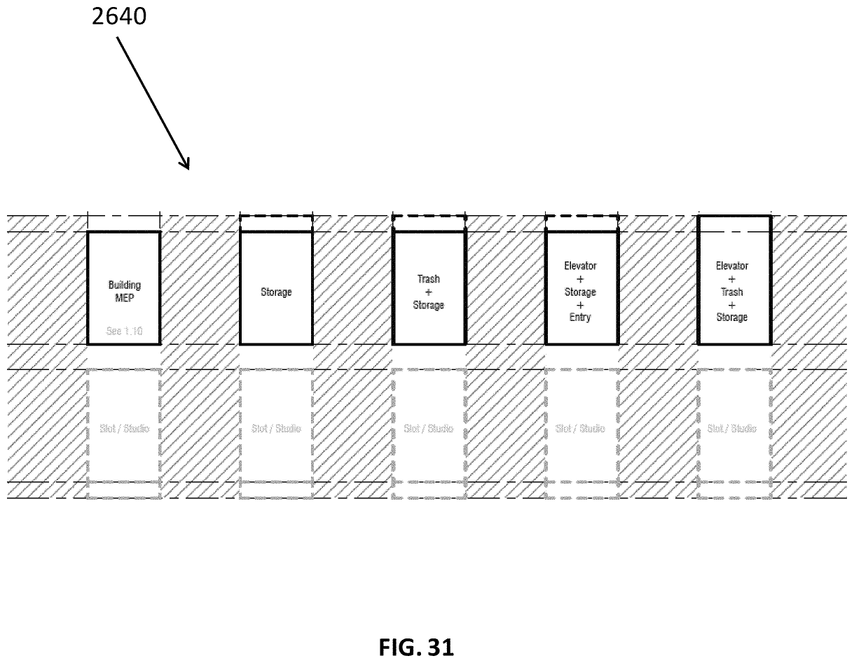

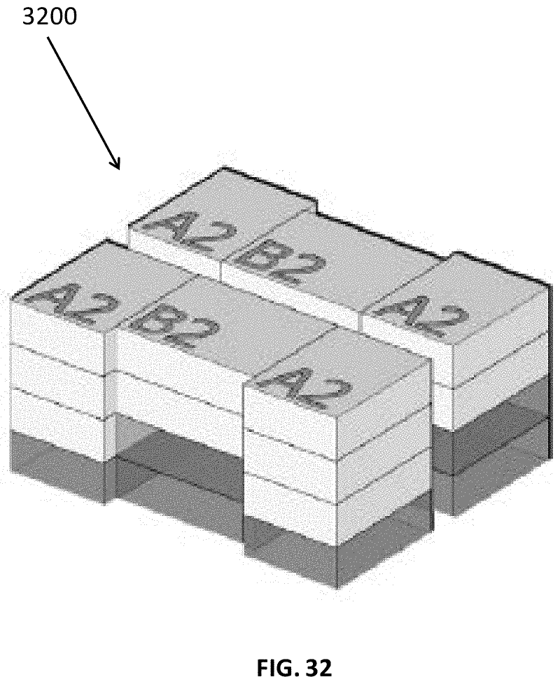

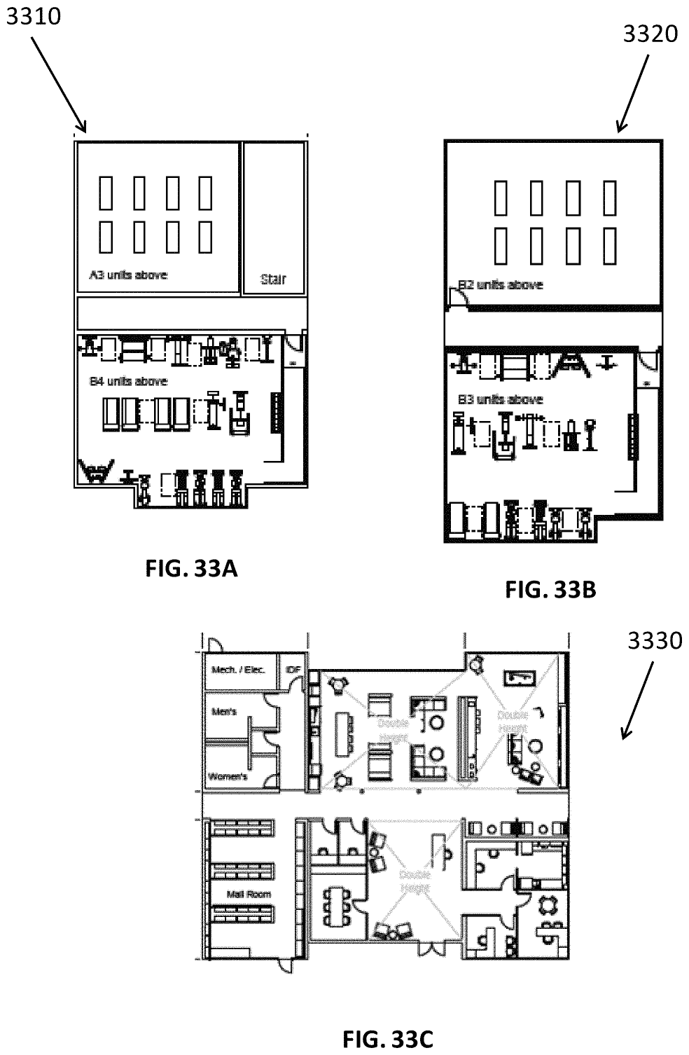

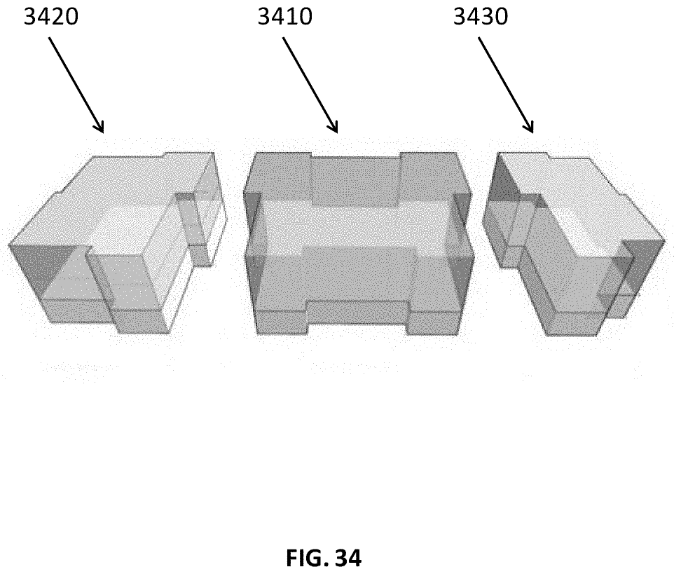

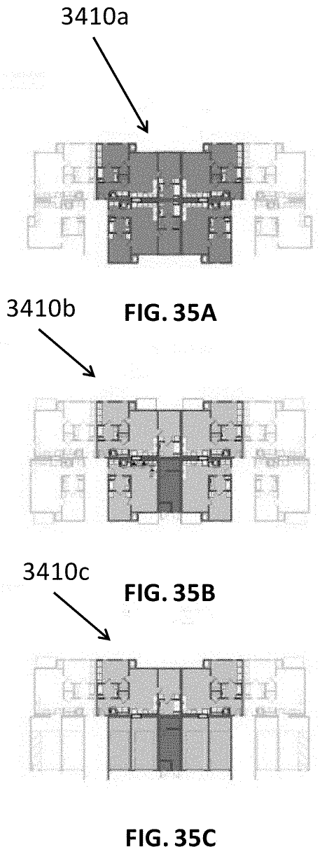

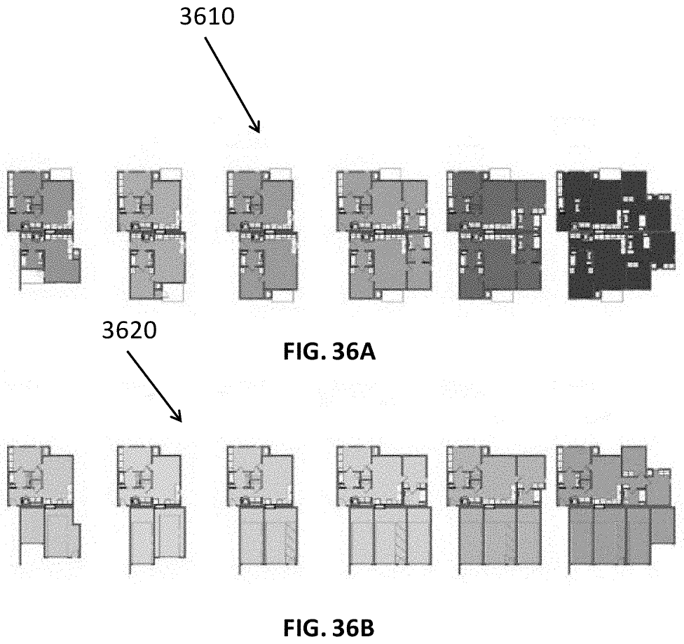

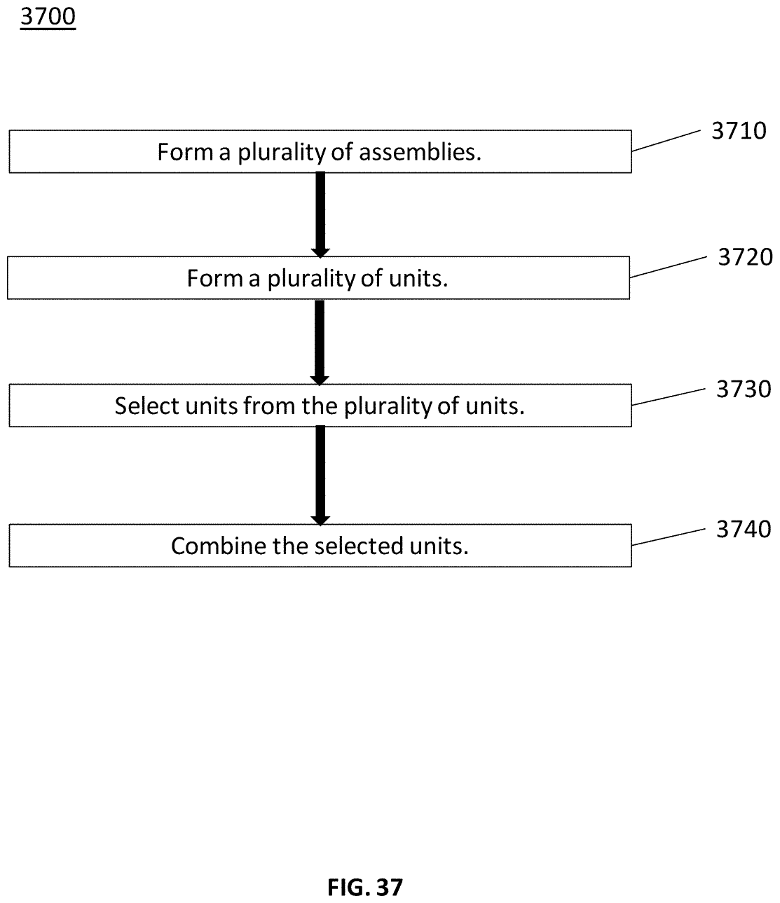

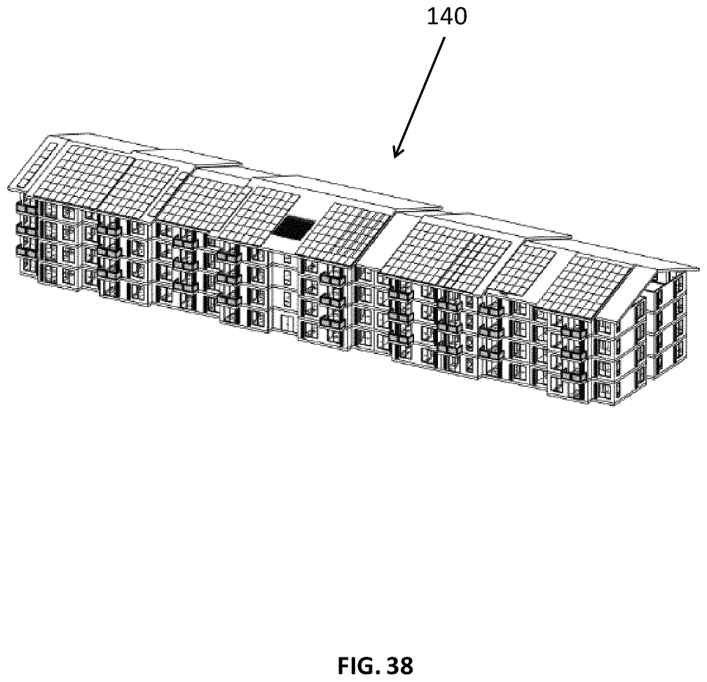

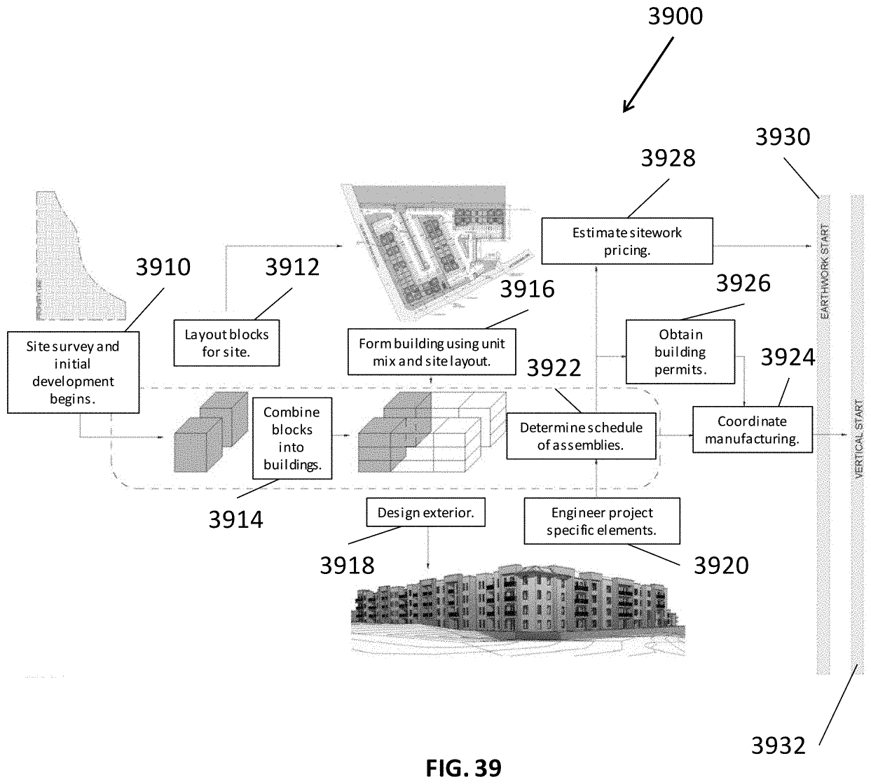

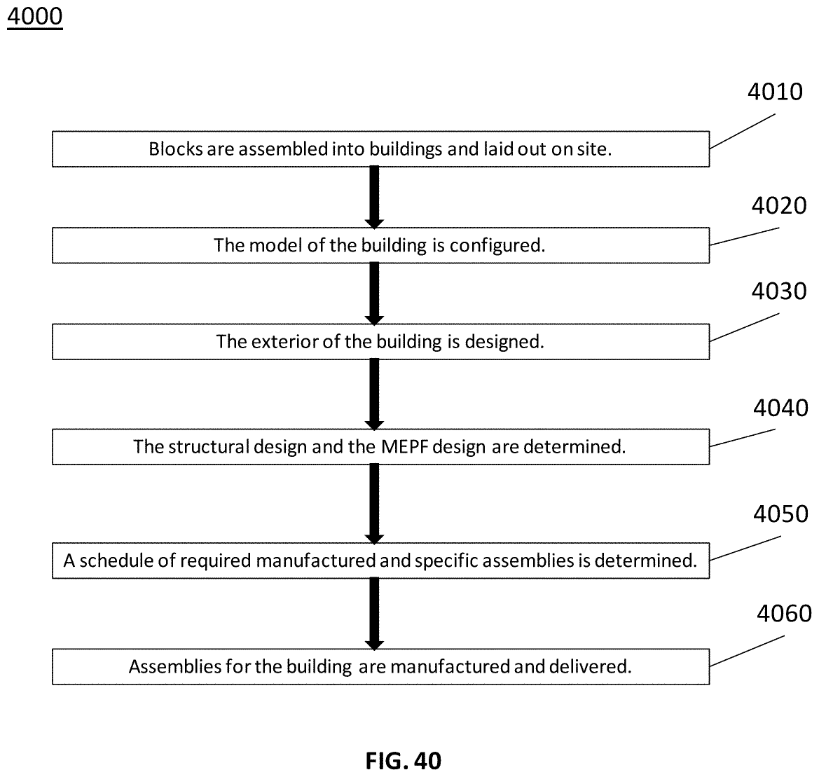

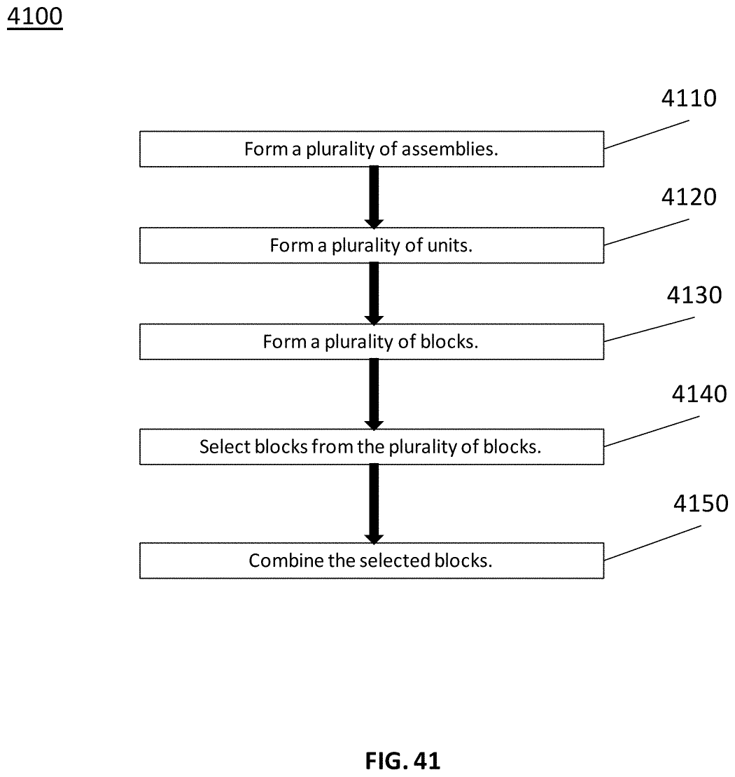

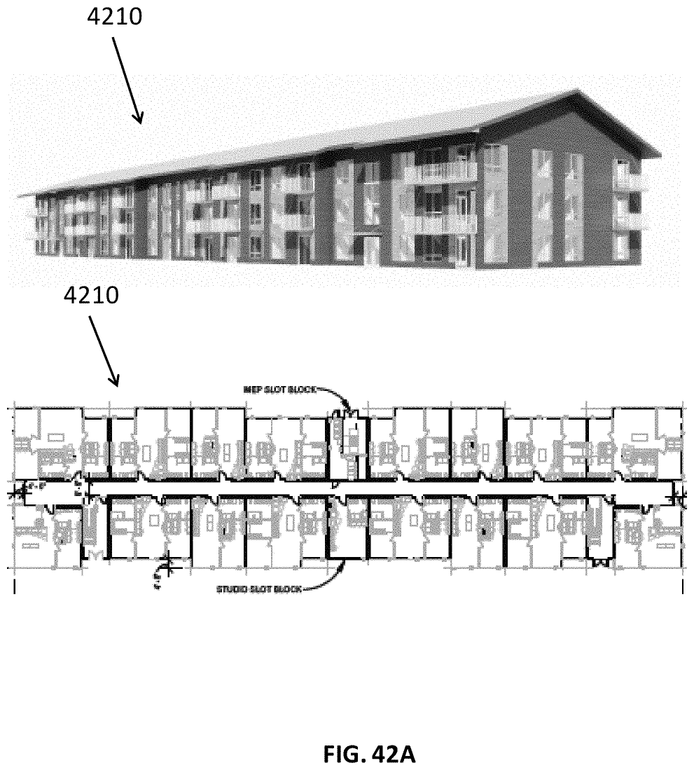

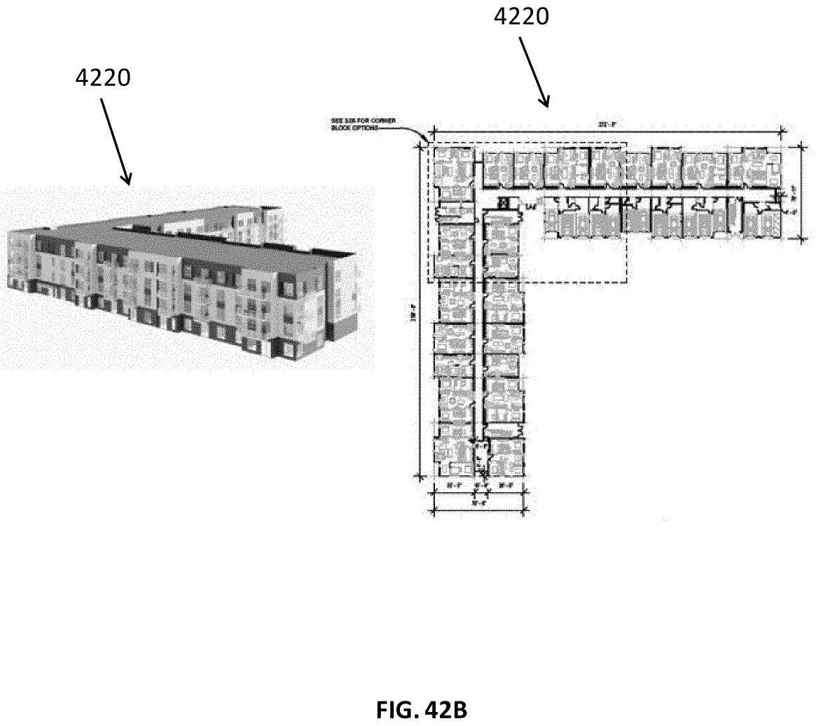

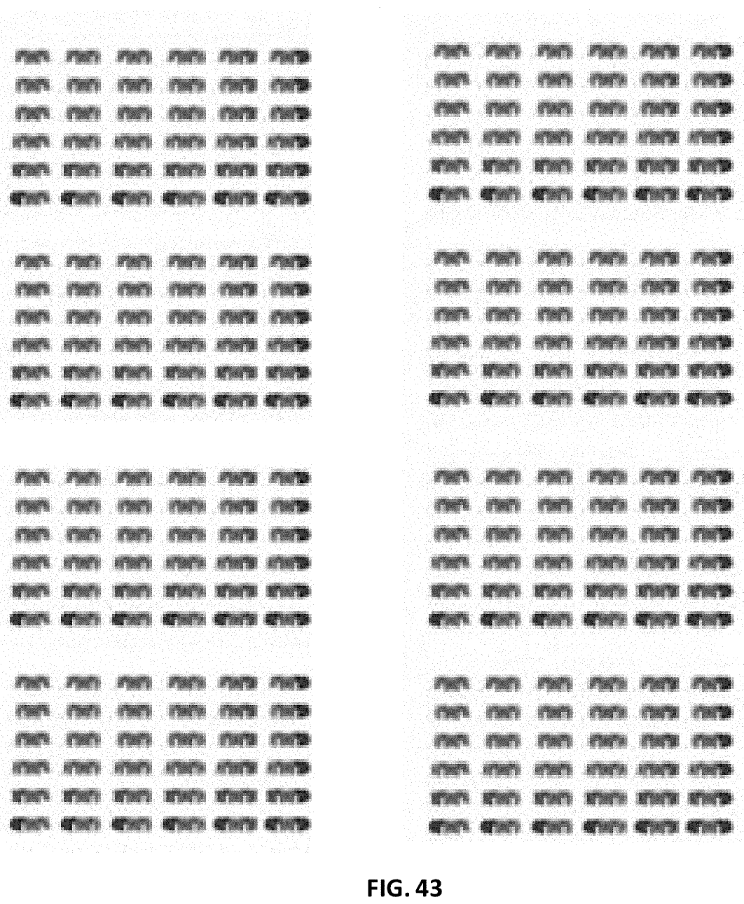

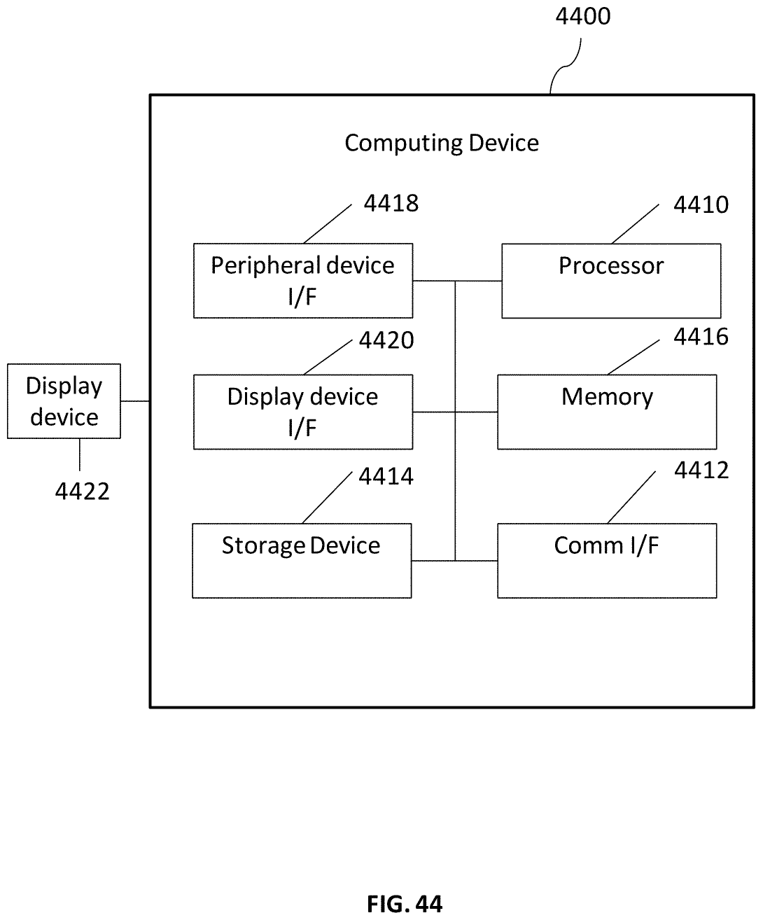

FIG. 11A is a figure of the vertical conveyance 1100 category of assemblies 110. The vertical conveyance 1100 category consists of “standard” elements. The vertical conveyance 1100 is established by block 130 choices. Vertical conveyances 1100 may include elevators 1110 and stairs 1120.

FIGS. 11B-11C show an elevator system 1110. The elevator may be an off the shelf assemblies including the entire shaft or hoistway and elevator cab. The assemblies correspond to an elevator pit and building systems connections per manufacturer specifications. FIG. 11B shows the hoistway or cab plan 1112. FIG. 11C shows the elevator or shaft section 1114.

FIG. 11D shows a perspective view of a four level stairway 1120. 11E-11H shows a four level stairway plan. However, the stair assembly 1120 may flex from three to four stories and can account for minor changes in ground level exiting elevation. A minimum of two stairs are required for every building 140. FIG. 11E shows the ground level plan 1122. FIG. 11F shows the first floor level plan 1124. FIG. 11G shows the second floor level plan 1126. FIG. 11H shows the third floor level plan 1128.

FIG. 12A is a figure of the MEP system 1200 category of assemblies 110. The building MEP systems 1200 category consists of “configurable” elements. The building's central hot water and electrical systems originate in a slot block of the building as described herein.

FIG. 12B shows the first level 1210 of an exemplary MEP system 1200. The first level 1210 includes a main electrical system 1212, a plumbing chase 1214, and water/fire service 1216. At the exterior wall, a space is provided for the fire and water service 1216 entrance and an exterior door is provided for fire department access. Space is also allocated for a domestic water booster pump in the water/fire service 1216 room. A horizontal chase from the domestic hot water (DHW) room to the hallway spaces allows piping to access the remainder of the building. The remaining area of the ground floor is to be the electrical service entrance, disconnects, and the meter sticks required for the ground level.

FIG. 12C shows the middle level 1220 of an exemplary MEP system 1200. The middle level 1220 includes a utility closet 1222, plumbing chase 1224, electrical space 1226, and DHW plant 1228. A three story building will include one middle level MEP node 1220. A four story building will include two stacked middle level MEP nodes 1220. Space for a central domestic heating plant is provided at the outermost area of the MEP node 1220. The DHW room 1228 stacks directly above the water entrance room 1216 to protect the power service from water in the event of a rupture. A horizontal chase 1224 from the DHW room 1228 to the hallway spaces allows piping to access the remainder of the building. A small utility room 1222 near the hallway provides storage for building maintenance supplies. As on the first level 1210, the remaining area of the utility node is dedicated to the electrical distribution.

FIG. 12D shows the top level 1230 of an exemplary MEP system 1200. The top level 1230 includes a utility room 1232, electrical space 1234, and an exterior condenser porch 1236. On the top level 1230, the exterior of the MEP utility node is open to the ambient conditions; it is in effect a “porch” 1236. As some equipment is required to be outside, this porch 1236 eliminates the need for a depressed roof well. Such equipment includes outdoor split heat pumps for air conditioning of core amenity areas, hallways, or elevators. A larger utility room 1232 provides additional storage for building maintenance supplies. The remaining area of the utility node is dedicated to the electrical distribution.

FIG. 13A is a figure of the terminal utilities 1300 category of assemblies 110. The terminal utilities 1300 category consists of “standard” elements. The terminal utilities are established by unit 120 and block 130 choices. The terminal utilities 1300 include a shaft assembly 1310 and an electrical load center assembly 1320.

FIG. 13B shows a shaft assembly 1310. Shaft assembly 1310 options may include bathroom exhaust systems, kitchen exhaust systems, dryer exhaust systems, and enhanced ventilation systems. Each bathroom is provided a bathroom exhaust system with continuous exhaust air flow, which allows the use of less air cfm per standard/code. Exhaust discharge will be routed up through the rated shaft enclosure. Ductwork is wrapped with fire wrap insulation. Each individual fan runout is protected with a back-draft damper. Roof penetration is protected with gooseneck discharge.

Kitchen exhaust is provided by an integral fan over the range hood/microwave combo unit and operates intermittently as switched on by the occupant. The ductwork for the kitchen exhaust system is routed up through a rated shaft enclosure individually. Ductwork is wrapped with fire wrap insulation and protected utilizing a listed assembly. The ductwork discharges through roof gooseneck.

Dryer exhaust is routed up through a shaft enclosure individually and discharged through roof gooseneck.

Enhanced ventilation systems are optional. These systems are higher performing systems that reduce life-cycle costs. These systems include an energy recovery ventilator or a heat recovery ventilator located above the bathroom. The higher performing system use identical exhaust pathways and replace the requirement for individual exhausts. Benefits to this system include a reduction in annual energy cost and a completely decoupled ventilation system.

FIG. 13C shows an electrical load center assembly 1320. The electrical load center assembly 1320 is a manufactured assembly that pre-wires the unit 120 electrical boxes. The electrical load center assembly 1320 is akin to a break panel. The assembly 1320 takes electricity from a central feed and distributes the current to various loads or branch circuits which feed the various sockets, lighting, and appliances.

FIG. 14A is a figure of the casework category 1400 of assemblies 110. The casework 1400 category consists of “standard” elements. The casework 1400 is established by unit 120 choices. This category includes kitchen islands, pantries, and closets along with other casework 1400 that is not delivered to the site as part of the kitchen or bath kit, which are described in more detail herein. The casework 1400 closets allow for a highly-configurable closet design that may be less expensive than a traditional drywall closet. This system is highly modular and can accept a wide range of accessories and finishes. Standard closets may be 2′ deep and range in width. Narrow closets cannot be fitted with closet accessories and are best suited as a pantry or linen closet. Closets 2′ and over can be fitted with all standard closet accessories. The most basic closet system is a shelf and rod closet option. FIG. 14B shows closet accessories 1410 including hanging rods 1412, accessory trays 1414, jewelry trays 1416, trousers racks 1418, shoe racks 1420, clothing baskets 1422, tie racks 1424, pull-out mirrors 1426, and pull-down hanging rods 1428.

FIG. 15A is a figure of the kitchen category 1500 of assemblies 110. The kitchen category 1500 consists of “standard” elements. The kitchen 1500 is established by unit 120 choices. The kitchen 1500 assembly is designed to accommodate ANSI Type A, Type B and CBC accessibility requirements. The kitchens 1500 are kitted for easy handling and shipping and safe and efficient installation on site. Kitchen islands may be used in addition to the standard kitchen to increase the kitchen amenity. FIG. 15B and FIG. 15C show example kitchens 1500a-b. The kitchens 1500a-b may include removable base cabinets 1510. FIG. 15D show example kitchen islands 1520a-c. These kitchen islands 1520 may be used in conjunction with the kitchens 1500a-b in FIGS. 15B and 15C.

FIG. 16A is a figure of the bathroom 1600 category of assemblies 110. The bathroom category consists of “standard” elements. The bathroom 1600 is established by unit 120 choices. At least two different bathroom plans may be included in the assembly library.

FIG. 16B shows a first bathroom plan 1600a. FIG. 16C shows a second bathroom plan 1600b. The bathrooms 1600 may include a tub or shower 1610, pocket doors 1620, toilet 1630, linen closet 1640, and removable base cabinet 1650. Bathrooms 1600 may be configured to be accessible. The bathroom plans 1600a-b are configurable to address accessibility requirements and are kitted for rapid installation on site.

FIG. 16D shows an exploded view of the bathroom kit 1600. The bathroom kit 1600 ships to the work site in an efficient crate form. The bath kit 1600 includes a bathtub enclosure 1610, a first sidewall sub-assembly 1612, a second sidewall sub-assembly 1614, a rear bracing sub-assembly 1616, a drop ceiling sub-assembly 1618, and a floor sub-assembly 1622. The first sidewall sub-assembly 1612, the second sidewall sub-assembly 1614, the rear bracing sub-assembly 1616, the drop ceiling sub-assembly 1618, and the floor sub-assembly 1622 may be made from wood, steel, or any sufficiently rigid material. As described in more detail herein, the first sidewall sub-assembly 1612, the second sidewall sub-assembly 1614, the rear bracing sub-assembly 1616, the drop ceiling sub-assembly 1618, and the floor sub-assembly 1622 form three sides, the top, and the bottom of the bath kit 1600 in crate form.

The bath kit 1600 may also include a plurality of crate contents 1625. The plurality of crate contents 1625 may include the removable base cabinet and sink 1650, the linen closet 1640, the toilet 1630, and finishing goods (for example towel racks, mirrors, hardware, lights, etc.). The plurality of crate contents 1625 may include only some of these bathroom components or may include additional bathroom components not listed. The plurality of crate contents 1625 may be loaded within the bathtub enclosure 1610 in the bath kit 1600 in crate form. By packing the plurality of crate contents 1625 within the bathtub enclosure 1610, the plurality of crate contents 1625 are protected by the bathtub enclosure 1610, the first sidewall sub-assembly 1612, the second sidewall sub-assembly 1614, the rear bracing sub-assembly 1616, the drop ceiling sub-assembly 1618 and the floor sub-assembly 1622. The plurality of crate contents 1625 are protected during shipping and handling of the bath kit 1600 in crate form. Loading the plurality of crate contents 1625 within the bathtub enclosure 1610 is also space efficient.

The bath kit 1600 may also include at least one drywall section 1632. The bath kit 1600 may also include a plurality of cross braces 1634 and a drywall carrier 1636. The cross braces 1634 and the drywall carrier 1636 may be connected to the first sidewall sub-assembly 1612, the second sidewall sub-assembly 1614, the drop ceiling sub-assembly 1618 and/or the floor sub-assembly 1622. The plurality of cross braces 1634 provides structure and stability to the bath kit 1600 in crate form. The plurality of cross braces 1634 and/or the drywall section 1632 enclose and protect components loaded within the bathtub enclosure 1610 such as the plurality of crate contents 1625. Moreover, the drywall carrier 1636 is designed to hold or support the drywall section 1632. Together, the drywall section 1632, cross braces 1634, and drywall carrier 1636 make up the fourth and final side of the bath kit 1600 in crate form. Alternatively, the cross braces 1634 and/or drywall carrier 1636 may be excluded and the drywall section 1632 acts as the fourth and final side of the bath kit 1600 in crate form. If the cross braces 1634 and/or drywall carrier 1636 are excluded, the drywall section 1632 may be secured to the first sidewall sub-assembly 1612, the second sidewall sub-assembly 1614, the drop ceiling sub-assembly 1618 and/or the floor sub-assembly 1622. This fourth side encloses the plurality of crate contents 1625 and the bathtub enclosure 1610.

The bath kit 1600 may also include a lower shelf 1642 and an upper shelf 1644 when the bath kit 1600 is in crate form. The lower shelf 1642 and the upper shelf 1644 hold and/or support the plurality of loaded crate contents 1625. Moreover, the lower shelf 1642 and upper shelf 1644 may be temporarily connected to one or more components of the sub-assembly 1612, 1614, 1618, 1622 when the bath kit 1600 is in crate form. For example, the lower shelf 1642 and upper shelf 1644 may be connected to the drop ceiling sub-assembly 1618. This connection takes the load from the plurality of crate contents 1625 off the bathtub enclosure 1610 when the bath kit 1600 is in crate form. Taking the load off the bathtub enclosure 1610 helps protect the bathtub enclosure 1610 from damage during shipping and handling.

The bath kit 1600 in crate form may also include a corrugated tub protector 1646 and/or foam inserts 1648. These components protect the bathtub enclosure 1610 and plurality of crate contents 1625 during shipping and handling.

The bath kit 1600 may also include a shower tree sub-assembly 1652 and an overflow sub-assembly 1654. The shower tree sub-assembly 1652 and the overflow sub-assembly 1654 are secured to a sidewall sub-assembly 1612, 1614 when the bath kit 1600 is in crate form.

FIG. 16E shows a bathroom kit 1600 in crate form. The bath kit 1600 is assembled in crate form. The first sidewall sub-assembly 1612, second sidewall sub-assembly 1614, rear bracing sub-assembly 1616 (not visible), drop ceiling sub-assembly 1618, and floor sub-assembly 1622 connect to form a sub-assembly 1621. The sub-assembly 1621 may be connected via connectors such as nails, screws, or bolts. The first sidewall sub-assembly 1612 forms a first side of the bath kit 1600 in the crate form. The second sidewall sub-assembly 1614 forms a second side of the bath kit 1600 in the crate form. The rear bracing sub-assembly 1616 forms a third or rear side of the bath kit 1600 in the crate form (not visible). The drop ceiling sub-assembly 1618 forms the top of the bath kit 1600 in the crate form. The corrugated tub protector 1646 may be connected to the drop ceiling sub-assembly 1618 to keep the corrugated tub protector 1646 in place and the bathtub enclosure 1610 protected during shipping. The floor sub-assembly 1622 forms the bottom of the bath kit 1600 in the crate form. The design of the floor sub-assembly 1622 may include recesses or a space. The recesses or space allow construction equipment, such as a forklift, to pick up and move the bath kit 1600 in crate form.

The drywall section 1632 may form the fourth side of the bath kit 1600 in crate form. The bath kit 1600 may also include the plurality of cross braces 1634 and the drywall carrier 1636 as the fourth wall of the bath kit 1600 in crate form. The bath kit 1600 assembled in crate form creates a space efficient, well protected crate to transport many essential bathroom components to the job site. The crate reduces cost and waste by using bathroom components to form the crate in which they are shipped. The bath kit 1600 in crate form may be wrapped and/or sealed to protect the bath kit 1600 components from damage during shipping and handling.

FIG. 17A is a figure of the interior finish 1700 category of assemblies 110. The interior finish 1700 category consists of “configurable” elements. The interior finish 1700 relies on sourcing tiers. The interior finishes 1700 may be organized in tiers for rank and categorization of materials. The tiers may also be used as pricing guidance. The interior finish 1700 category encompasses all finishes that are not captured by other prefabricated kits or assemblies. FIG. 17B shows examples of finishes 1710. FIG. 17C shows examples of lighting elements 1720. FIG. 17D shows examples of appliances 1730.

FIG. 18 shows a flow chart of a method for creating an assembly library 1800. In step 1810, a plurality of building component categories are defined. The building component categories include wall panels, floor panels, bath kits, and kitchen kits. The building component categories may include the fifteen categories of common building components discussed above. The building components are tied to building functions. In step 1820, a plurality of building components based on unit, block, and/or building decisions are created. For example, a variety of wall panels, floor panels, kitchens, and bathrooms may be created. The components may vary based on material, cost, and size. The number of different components should balance standardization with flexibility. The number of different components should allow each component to be repetitively used within a unit or multiple units, yet there should be a number of options to allow the consumer to customize the building. In step 1830, the plurality of building components is categorized into the plurality of building component categories. Selected building components from the categorized building components are configured to make up a plurality of units. Selected units from the plurality of units are configured to make up a plurality of blocks. Selected blocks from the plurality of blocks are configured to make up a building.

Units

FIG. 19 shows a unit 120. A unit 120 is comprised of specific assemblies 110 from the assembly library. A unit 120 may be an apartment. Units 120 may be designed to accommodate senior independent living and market rate apartments. A unit 120 may be a studio, one bedroom, two bedroom, etc. The unit 120 library may be comprised of a plurality of unit 120 plans or options. A library of nine unit 120 plans minimizes the number of distinct wall panels 600, floor panels 500, and manufactured assemblies 110 included in the project while providing desirable unit 120 sizes and mix to customers. However, more or less units 120 may be included in the unit library. Interior finishes 1700 of the units 120 may be configurable within coordinated pre-selected finish tiers based on material quality and expense. Each unit 120 plan may accommodate ANSI Type A, ANSI Type B, or California Building Code (CBC) accessibility requirements. There may be “standard” units and “accessible” units. Standard units meet at least ANSI Type B, CBC, and Fair Housing Act (FHA) code requirements. Accessible units meet at least ANSI Type A and FHA code requirements. The number and location of accessible units 120 in a block 130 and a building 140 are based on jurisdictional need.

A unit 120 library comprises the plurality of different units 120. The unit 120 size range and square footage for different unit 120 types is determined based on a national data set for market rate and senior properties. The unit 120 library includes studio apartments that may have square footages ranging between 250 sq. ft. to 1000 sq. ft., one bedroom apartments ranging from 400 sq. ft. to 1500 sq. ft., two bedroom apartments ranging from 600 sq. ft. to 2000 sq. ft., and three bedroom apartments ranging from 800 sq. ft. to 2500 sq. ft. These ranges are merely exemplary and units may encompass different ranges. The unit sizes are designed to meet a variety of market requirements.

FIG. 20 shows an optimized unit 120. The optimized units 120 are laid out to enhance living space and use manufactured components from the assembly library. Optimized units 120 typically have repeating components or parts to reduce complex, manual field-work. For example, an optimized unit has repeating wall panels 600 and floor panels 500 to simplify the manufacturing process of the prefabricated assemblies 110. Optimized units 120 also typically have long, straight walls with continuous bearing lines 2010. Longer, straighter, and fewer walls simplify the structure, prefabricated wall panel manufacturing, and shipping. Longer, straighter, and fewer walls also allows for fewer panels, fewer picks, fewer connections and more efficient shipping. Straight and continuous structural bearing lines 2010 simplify floor panels 500, wall panels 600 and foundation bearing systems. Laundry/closet designs 2020 incorporate pre-engineered, panelized utility walls, optimized for space efficiency and installation. Casework laundry doors seamlessly integrate into a cabinet run. Pocket doors 2030 ship inside wall panels and save space by greatly reducing accessibility clearances. Bathrooms 2040 are pre-designed, pre-engineered to install in approximately a day. Bathrooms 2040 are designed for optimal livability, efficiency and accessibility compliance. Repeatable bathroom 2040 layouts reduce the cost and time to develop a project. Components within bath kits are configurable to customize the project. Kitchens 2050 are pre-designed, pre-engineered and optimized for cost, manufacturing MEP simplification and accessibility. Permanent and furniture islands are available. Fewer walls simplify pre-fabricated wall panel manufacturing. Kitchen, bathroom and laundry assemblies incorporate furred-out utility walls, allowing for pre-assembly and optimization of MEP system engineering, installation and assembly. Square footage and wall panels are saved by using casework closets 2060.

FIGS. 21A-E show an exemplary unit library consisting of nine optimized units 120. Although a nine unit library is depicted, the unit library may include more or less units 120. The number of different units 120 should balance standardization with flexibility. The number of different units 120 should allow each unit to be repetitively used within blocks 130 or a building 140, yet there should be a number of options to allow the consumer to customize the building 140. FIG. 21A show plans of studio or guest suite units 2110a-b. FIG. 21B shows plans of one bedroom units 2120a-b. FIG. 21C shows a plan of a one bedroom with a den or two bedrooms with one bath unit 2130. FIG. 21D shows plans of two bedroom units 2140a-c. FIG. 21E shows a plan a three bedroom unit 2150. The units 120 in the unit library include a variety of different components from the assembly 110 library. Each unit 120 includes wall panels 600, floor panels 500, a bathroom kit 1600, and a kitchen kit 1500 from the assembly 110 library. The components may be repeated throughout the unit 120 and/or throughout different units 120 to simplify manufacturing and reduce costs. Because these components are prefabricated, units 120 are quickly and efficiently assembled on the work site. Moreover, because these components are prefabricated, some if not most of the bill of materials for a building 140 may be generated at the unit 120 level.

FIGS. 22A-E show floor panel plans for each of the units shown in FIGS. 21A-E. The floor panel plans 2210a-b in FIG. 22A correspond to the studio or guest suite units 2110a-b shown in FIG. 21A. The floor panel plans 2220a-b in FIG. 22B correspond to the one bedroom units 2120a-b shown in FIG. 21B. The floor panel plan 2230 in FIG. 22C corresponds to the one bedroom with a den or two bedrooms with one bath unit 2130 shown in FIG. 21C. The floor panel plans 2240a-c in FIG. 22D correspond to the two bedroom units 2140a-c shown in FIG. 21D. The floor panel plan 2250 in FIG. 22E corresponds to the three bedroom unit 2150 shown in FIG. 21E. The plans minimize the number of floor panels per unit and the number of floor panels through the plurality of units. The floor panels are dimensioned to align with bearing walls to simplify the design and installation. The size of each floor panel allows easy shipping and handling. Floor panels associated by unit type minimize the variation between floor panels and simplify manufacturing of the floor panels.

FIGS. 23A-E show garage plans that are options for each of the units shown in FIGS. 21A-E. The garage plans 2310a-b in FIG. 23A correspond to the studio or guest suite units 2110a-b shown in FIG. 21A. The garage plans 2320a-b in FIG. 23B correspond to the one bedroom units 2120a-b shown in FIG. 21B. The garage plan 2330 in FIG. 23C corresponds to the one bedroom with a den or two bedrooms with one bath unit 2130 shown in FIG. 21C. The garage plans 2340a-c in FIG. 23D correspond to the two bedroom units 2140a-c shown in FIG. 21D. The garage plan 2350 in FIG. 23E corresponds to the three bedroom unit 2150 shown in FIG. 21E. The garages may be located on the ground floor for each block 130. The layouts of the garages are dictated by the structural design of the units above. Alternatively, oversized garages and private storage spaces may be included.

FIG. 24 shows a flow chart of a method of forming units 2400. In step 2410, a plurality of assemblies is formed. The plurality of assemblies include the assemblies described above. The assemblies of the plurality of assemblies include the details and embodiments previously discussed. In step 2420, assemblies are selected from the plurality of assemblies. At least a plurality of wall panels, floor panels, at least one bathroom, and a kitchen are selected to form a unit. Wall panels and floor panels are chosen to form a unit so that the same floor panel and wall panel design may be repetitively used. Assemblies are chosen to optimize the unit as discussed above. Some components of the assemblies may be configured or customized by a user, thereby customizing the resulting unit. In step 2430, the selected assemblies are combined to form the unit. The unit may be a studio, guest suite, one bedroom, one bedroom with a den, two bedroom, or three bedroom unit. The assemblies are combined to maximize square footage and optimize living space. Multiple units may form a unit library. Each unit within the unit library is different.

Blocks

FIG. 25 shows a block 130. Blocks 130 comprise specific units 120 from the unit library and specific assemblies 110 from the assembly library. A block 130 may include a plurality of stacked units 120 separated by a corridor. A block 130 may include at least two stacked units 120. Preferably, a block 130 includes 2-4 stacked units 120. Some assemblies may be applied at the block 130 stage. For example, a roof 700 tops the highest level unit 120 in the block 130.

All blocks 130 are made up of a variable mix of units 120 and assemblies 110 from seven of at least fifteen classification categories of building components. The seven assembly 110 components in blocks 130 include floor panels 500, wall panels 600, roof assemblies 700, fenestration 800, vertical conveyance 1100, building MEP 1200, and interior finishes 1700. Not all blocks 130 include assemblies 110 from all categories. At a minimum, all blocks 130 include units 120, floor panels 500, a roof assembly 700, and interior finishes 1700. Vertical conveyance 1100 and building MEP 1200 are exclusive to slot blocks, stair blocks, and corner blocks as described herein.

FIGS. 26A-26B show a block 130 library for a corridor style building. The block library for a corridor style building includes corner blocks 2610, in-line blocks 2620, end blocks 2630, and slot blocks 2640. A fixed offering of blocks 130 from which a building 140 can be pieced together addresses variable unit 120 mixes and limits manufacturing variability. All types of blocks 130 in the block library are configured to flex from three stories with or without a ground floor garage to four stories with or without a ground floor garage.

The corner blocks 2610 may include three units 120 per floor and a slot block 2640. However, the corner block 2610 may include more or less units 120. The three units 120 per floor may consist of a large two bedroom unit 2612 or a three bedroom unit 2612, and two one bedroom units 2614 from the unit library. The large two bedroom unit or three bedroom unit 2612 is positioned in the outside corner position. The two one bedroom units 2614 are in adjacent positions across the corridor from the large two bedroom unit or three bedroom unit 2612. The slot block 2640 is located in the interior corner. The corner block 2610 may also include a vertical conveyance 1100 from the assembly library. The corner block 2610 may form an approximate 90 degree angle or an oblique angle.

The in-line blocks 2620 consist of units 120 of the same type, stacked and rotated 180 degrees across the corridor from one another. Studio, one bedroom, and two bedroom unit types each have corresponding in-line blocks. For example, there is at least one studio unit in-line block 2622, at least one one bedroom unit in-line block 2624, and at least one two bedroom unit in-line block 2626. In-line blocks may also have a mix of units.

The end blocks 2630 include two discrete units and an exit stair. The two discrete units include one larger unit 2632 and one smaller unit 2634. The larger unit 2632 may comprise a large two bedroom unit or a three bedroom unit. The small unit 2634 is positioned adjacent to the vertical conveyance or stair block 1100. The small unit 2634 may comprise a large one bedroom with den unit or small two bedroom unit.

The slot blocks 2640 consist of two cross-corridor flex spaces. Each slot block 2640 may be used independently or together to provide space for the building entry, vertical circulation, mechanical space, storage, or other supporting building component.

FIGS. 27A-D show perspective views of the in-line blocks 2620. FIG. 27A shows three studio unit in-line block options 2622a-c. The first studio block option 2622a includes all first studio units 2710a. The second studio block option 2622b includes first studio units 2710a and second studio units 2710b. The third studio block option 2622c includes all second studio units 2710b. FIG. 27B shows three one bedroom unit in-line block options 2624a-c. The first one bedroom block option 2624a includes all first one bedroom units 2720a. The second one bedroom block option 2624b includes first one bedroom units 2720a and second one bedroom units 2720b. The third one bedroom block 2624c option includes all second one bedroom units 2720b. FIG. 27C shows five two bedroom unit in-line block options 2626a-e. The five options 2626a-e include different layouts including three different two bedroom units 2730a-c. FIG. 27D shows an in-line block 2628 including a stair unit 2740, a one bedroom unit 2720a, and a two bedroom unit 2730a.

FIG. 28A shows perspective views of the end blocks 2630a-d. FIG. 28B shows an example plan view of an end block 2630. The end block 2630e may include an expanded corridor 2810.

FIG. 29A shows perspective views of the corner block options 2610a-b. FIG. 29B shows an example plan view of a corner block 2610c.

FIGS. 30A-D shows plan views of four different corner block options 2610d-g. The different corner block options 2610d-g may include a different mix of units.

FIG. 31 depicts a slot block plan option 2640. The slot block 2640 may accommodate required and/or optional building components. The slot block 2640 may house a number of different assemblies 110. The slot block 2640 may house elements including hot water systems, elevators, trash chutes, tenant storage, building entry, and additional staircases when applicable. Slot block 2640 may also provide a passageway through the building where necessary. Each building 140 includes a minimum of one slot block 2640.

FIG. 32 shows an example of an amenity block 3200. The amenity blocks 3200 may be located on the ground or first floor level below units 120. The layout and design of the amenity blocks 3200 are flexible to fit specific needs of the buildings 140.

FIGS. 33A-C show plans for three amenity block options 3200 included in the block library. FIG. 33A shows a plan for an amenity block 3310 which fits in an end block below units 120. FIG. 33B shows a plan for an amenity block 3320 which fits in an in-line block below units 120. FIG. 33C shows a plan for an amenity block 3330 which may form a central block. The central block may include units 120 above the amenity block.

FIG. 34 shows a block library for a garden style building. The block library for a garden style building includes a central block 3410, a first end block 3420, and a second end block 3430. A fixed offering of blocks from which a building can be pieced together addresses variable unit 120 mixes and limits manufacturing variability. All types of blocks 130 in the block library are configured to flex from three stories with or without a ground floor garage to flour stories with or without a ground floor garage.

FIGS. 35A-C show block option plans 3410a-c for the central block 3410. FIG. 35A shows an example block options 3410a for levels 2 and up. FIG. 35B shows an example block option 3410b for the first level. FIG. 35C shows an example block option 3410c for a tuck-under level.

FIGS. 36A-B show block option plans for the first end block 3420 and the second end block 3430. FIG. 36A show end block plans 3610 for levels 1 and up. FIG. 36B show end block plans 3620 for the tuck-under level. All end modules may be mirrored to apply to the first end block 3420 or the second end block 3430.

FIG. 37 is a flow chart of a method of forming blocks 3700. In step 3710, a plurality of assemblies is formed. The plurality of assemblies include the assemblies described above. The assemblies of the plurality of assemblies include the details and embodiments previously discussed. In step 3720, assemblies are selected from the plurality of assemblies. At least a plurality of wall panels, floor panels, at least one bathroom, and a kitchen are selected for form a unit. Wall panels and floor panels are chosen to form a unit so that the same floor panel and wall panel design may be repetitively used. Assemblies are chosen to optimize the units as discussed above. Some components of the assemblies may be configured or customized by a user, thereby customizing the resulting unit. The plurality of units includes studio, one bedroom and two bedroom units. The plurality of units has different square footages and layouts. In step 3730, units are selected from the plurality of units to form a block. Units are chosen based on the type of unit, the square footage, and layout of assemblies. The same type of units may be selected to make a block or different types of units may be selected to make a block. In step 3740, the selected units are combined to form a block. The block is a portion of the building. The block may be a central block, an end block, a corner block, a slot block, or an in-line block. Multiple blocks may be formed to create a block library.

Buildings

FIG. 38 shows a building system 140. A building system 140 is comprised of fixed blocks 130, unique units 120, and unique assemblies 110. The fixed blocks 130 allow flexibility in building 140 form. Any number of linear, “L,” “U,” “T,” or “E” shaped buildings 140 are possible within the system. The building system 140 includes unique exteriors using the modulation inherent to the blocks 130, a defined library of fenestration options, exterior accessories and pre-approved exterior envelope materials. Because predefined blocks 130, units 120, and assemblies 110 comprise the building system 140, a list of assemblies 110 and materials required for construction can be quickly generated.

The predefined blocks 130 are used as a site planning tool for the building system 140. The blocks 130 represent real, dimensionally accurate building components. The blocks 130 selected to form the building system 140 contain a variable mix of units 120. Different units 120 may be selected to provide a site specific unit mix. Adjusting the blocks 130 adjusts the unit 120 mix and unit 120 layout of the building system 140. Because the blocks 130 are real, known collection of building components, the building system 140 is quickly and easily defined by the blocks 130. The blocks 130 ultimately condense the project delivery timeline of the building system 140. After choosing the blocks 130 to form the building system 140, the actual dimensions, gross square footage, net rentable square footage, unit counts, and unit mix of the building system 140 are known. Additionally, decisions such as quantity and locations of garages, balconies, accessible units, building entry, stairs, elevators, building MEP connections, amenity program elements, and roof type are quickly captured with the selection of blocks 130 and the layout of the blocks 130 to form the building system 140. These building decisions along with the size, footprint, and unit 120 count and mix can all be made early in the decision making process because the assemblies 110, units 120, and blocks 130 are predefined, which allows a highly accurate estimate of the total building cost during the early design stages.

FIG. 39 shows a diagram of a building system work flow chart 3900. A survey of the site and initial development determines what predefined blocks are selected (3910). The selected blocks are laid out on the site (3912) and combined to form a building (3914). The formation of the building depends on the desired unit mix, unit layout, and site layout (3916). The design of the exterior is determined based on the building formation or layout and desired aesthetics (3918). Once the building layout is determined, project specific engineering can be performed (3920). The schedule of assemblies required and bill of materials can be determined based on the building layout and engineered elements (3922). Based on the schedule of assemblies, the manufacturing of assemblies can begin (3924), building permits can be obtained (3926), and an estimate of the project can be determined (3928). Finally, the earthwork can start (3930) and then the building can be constructed (3932).

FIG. 40 shows a flow chart of the design process for the building system 4000. The design process for the building system can be broken down into phases including at least insight, design I, design II, design III, design IV and design V. During the insight phase 4010, blocks are assembled into buildings and laid out on site. The insight phase 4010 includes deciding number of stories of the building, the building footprint, the unit mix, the location of types of units, number and location of garages, amenity locations and strategy, and number and location of slot blocks. During the design I phase 4020, the model of the building is configured. The design I phase 4020 includes a code review of the building model, confirming the building footprint, and developing the slot block program. At the end of the design I phase 4020, approximately 50% of the building component parts is determined. During the design II phase 4030, the exterior of the building is designed. The design II phase 4030 includes deciding fenestrations, the exterior cladding, balconies, the roof form, parapets and overhangs, interior finish level, MEPF, and the site plan is refined. At the end of the design II phase 4030, approximately 70% of the building component parts is determined. During the design III phase 4040, the structural design and the MEPF design are determined. The design III phase 4040 includes deciding the building foundation, shear panel design, floor panel design, common space design, MEP design, fire protection, initial site utility coordination, and specific interior finishes. At the end of the design III phase 4040, approximately 90% of the building component parts is determined. During the design IV phase 4050, a schedule of required manufactured and specific assemblies is determined. The design IV phase 4050 includes confirming the list of parts for the assemblies, coordinating the site, and determining unique building details. During the design V phase 4060, the assemblies for the building are manufactured and delivered. The design V phase 4060 includes reviewing shop drawings. By the design V phase 4060, 100% of building component parts is determined.

The table below represents decisions regarding configurable assembly designs made at different design stages of the building system work flow.

| | PHASE | | |
|---|---|---|---|
| | Decision/Inputs | | |
| | INSIGHT & | | |
| ASSEMBLY | DESIGN II | DESIGN III | DESIGN IV |
| | Number of stories | Determine loading | Architectural and |
| | selected | criteria based on | MEPF design 95% |
| | Unit mix and | project site: | complete. |
| | locations | Wind speed | |
| | determined | Wind topographic | |
| | Location of | factor | |
| | garages | Building exposure | |
| | determined | Ground snow load | |
| | Amenity strategy | Site class | |
| | determined | Spectral | |
| | Building footprint | acceleration | |
| | determined | Geotechnical | |
| | Roof form selected | recommendations | |
| | Number and | | |
| | location of slot | | |
| | blocks determined | | |
| | Fenestration | | |
| | selected | | |
| | Exterior cladding | | |
| | selected | | |
| | Balconies selected | | |
| ROOF | Truss geometry | Roof uplift connectors | No change. |
| TRUSSES | selected based on | selected based on | |
| | roof form. | calculated wind uplift | |
| | Square footage of | pressures. | |
| | roof calculated | | |
| | based on building | | |
| | footprint. | | |
| FLOOR PANELS | | | |
| Unit Panels | Number & type of | Flat panel edge | QC of MEPF |
| | floor panels | blocking added to | penetrations in |
| | identified. | floor panels if | floor. |
| | Panels may | required by seismic | Custom design of |
| | require blocking | analysis. | panels at amenity |
| | based on | | (if required). |
| | seismicity. | | |
| Corridor Panels | Corridor panels | MEP routed based | QC of MEPF |
| | identified based on | on building layout | penetrations in |
| | units selected. | and site. | floor. |
| | | Corridor panels | Custom design of |
| | | updated. | panels at amenity |
| | | | (if required). |
| WALL PANELS | | | |
| Non-Bearing | Wall panels | No change. | No change. |
| Partitions | quantities are | | |
| | identified based on | | |
| | units selected. | | |
| Interior Bearing | Wall panels are | No change. | No change. |
| Walls | selected based on | | |
| | units selected and | | |
| | number of stories. | | |
| | Wall panel | | |
| | quantities are | | |
| | identified. | | |
| Demising Walls | Wall panels and | Shear walls designed | QC of MEPF |
| | quantities are | based on lateral | penetrations in |
| | identified. | parameters. | wall. |
| | Quantity of ATS | ATS holdowns, | Custom design of |
| | holdowns & OSB | overturning studs, | panels at amenity |
| | sheathing | OSB sheathing | (if required). |
| | identified. | & fastening | |
| | Wall panels | identified. | |
| | include most studs, | | |
| | but not | | |
| | overturning studs | | |
| | at wall ends and | | |
| | ATS holdown | | |
| | sizes. | | |
| Corridor Walls | Wall panels and | Shear walls designed | QC of MEPF |
| | quantities are | based on lateral | penetrations in |
| | identified. | parameters. | wall. |
| | Quantity of ATS | ATS holdowns, | Custom design of |
| | holdowns & OSB | overturning studs, | panels at amenity |
| | sheathing | OSB sheathing | (if required). |
| | identified. | & fastening | |
| | Wall panels | identified. | |
| | include most studs, | | |
| | but not | | |
| | overturning studs | | |
| | at wall ends and | | |
| | ATS holdown | | |
| | sizes. | | |
| Exterior Walls | Wall panels are | No change. | No change. |
| | selected based on | | |
| | selected | | |
| | fenestration. | | |
| | Wall panels and | | |
| | quantities are | | |
| | identified. | | |
| FOUNDATIONS | Type of foundation | Foundation designed | QC of MEPF |
| | selected based on | based on site-specific | penetrations in |
| | preliminary site | soil parameters, | slab/footings. |
| | information. | lateral loads, and | |
| | Square footage of | finishes selected. | |
| | slab calculated | | |
| | based on building | | |
| | footprint. | | |

As discussed in the table above, many design decisions are determined early in the design process. The architectural and mechanical, electrical, plumbing and fire protection (MEPF) design is 95% complete before any construction begins. The use of blocks streamlines the design process of the building system. Many design decisions have already been determined by the predefined blocks. Yet, some decisions such as finishes, exterior of the building, exterior accessories, and roof are customizable and tailor the building system to the customer's wants and needs. This design process of designing a building system may be used for each new project.

FIG. 41. is a flow chart of a method of forming building system 4100. In step 4110, a plurality of assemblies is formed. The plurality of assemblies include the assemblies described above. The assemblies of the plurality of assemblies include the details and embodiments previously discussed. In step 4120, assemblies are selected from the plurality of assemblies to form a plurality of units. At least a plurality of wall panels, floor panels, at least one bathroom, and a kitchen are selected for form a unit. Wall panels and floor panels are chosen to form a unit so that the same floor panel and wall panel design may be repetitively used. Assemblies are chosen to optimize the units as discussed above. Some components of the assemblies may be configured or customized by a user, thereby customizing the resulting unit. The plurality of units include studio, one bedroom and two bedroom units. The plurality of units have different square footages and layouts. In step 4130, units are selected from the plurality of units to form a plurality of blocks. Units are chosen based on the type of unit, the square footage, and layout of assemblies. The same type of units may be selected to make a block or different types of units may be selected to make a block. The block is a portion of the building. The block may be a central block, an end block, a corner block, a slot block, or an in-line block. Multiple blocks may be formed to create a block library. In step 4140, blocks are selected to form a building. Blocks are selected to achieve a mix of units and to form a building that fits the site location. In step 4150, the selected blocks are combined to form a building.

FIGS. 42A-B show examples of resulting corridor style buildings. FIG. 42A shows a perspective view and a plan view of a linear corridor style building. The building in FIG. 42A is an efficient three story linear building 4210. The building 4210 does not contain integrated amenity spaces and represents a cost effective use to the corridor building system. This example 4210 includes two one bedroom blocks, four two bedroom blocks, one slot block, and two end blocks. This particular building has approximately 19,242 sq. ft. footprint, 58,726 total gross sq. ft., and is 84.3% efficient.

FIG. 42B shows a perspective view and a plan view of an “L” shaped corridor style building 4220. This example 4220 illustrates a larger style building. The building 4220 includes an integrated amenity space and other features which impact the building's net to gross square footage ration. This example 4220 includes two studio block, five one bedroom blocks, four two bedroom blocks, one corner block, and two end blocks. This particular building has approximately 30,002 sq. ft. footprint, 120,008 total gross sq. ft., and is 78.7% efficient.

FIG. 43 shows the base building options for garden style buildings using the predefined central blocks, first end blocks, and second end blocks. Combining the predefined blocks in various ways results in at least 288 base building geometries.

FIG. 44 is an example computing device 4400 that may be used to implement features described herein. The computing device 4400 includes a processor 4410 and communication interface 4412. The computing device 4400 may include a storage device 4414 and/or a memory device 4416. The computing device 4400 may also include a peripheral device interface 4418. The computing device 4400 may also include a display device interface 4420. The computing device 4400 may also include a display device 4422 which may be coupled to or included within the computing device 4400. The memory device 4416 may be or include a device such as a Dynamic Random Access Memory (D-RAM), Static RAM (S-RAM), or other RAM or a flash memory. The storage device 4414 may be or include a hard disk, a magneto-optical medium, an optical medium such as a CD-ROM, a digital versatile disk (DVDs), or BLU-RAY disc (BD), or other type of device for electronic data storage.

The communication interface 4412 may be, for example, a communications port, a wired transceiver, a wireless transceiver, and/or a network card. The communication interface 4412 may be capable of communicating using technologies such as Ethernet, fiber optics, microwave, xDSL (Digital Subscriber Line), Wireless Local Area Network (WLAN) technology, wireless cellular technology, BLUETOOTH technology and/or any other appropriate technology.

The peripheral device interface 4418 may be an interface configured to communicate with one or more peripheral devices. The peripheral device interface 4418 may operate using a technology such as Universal Serial Bus (USB), PS/2, BLUETOOTH, infrared, serial port, parallel port, and/or other appropriate technology. The peripheral device interface 4418 may, for example, receive input data from an input device such as a keyboard, a mouse, a trackball, a touch screen, a touch pad, a stylus pad, and/or other device. Alternatively or additionally, the peripheral device interface 4420 may communicate output data to a printer or a robot that is attached to the computing device 4400 via the peripheral device interface 4420.

The display device interface 4420 may be an interface configured to communicate data to a display device 4424. The display device 4424 may be, for example a monitor or television display, a plasma display, a liquid crystal display (LCD), and/or a display based on a technology such as front or rear projection, light emitting diodes (LEDs), organic light-emitting diodes (OLEDs), or Digital Light Processing (DLP). The display device interface 4420 may operate using technology such as Video Graphics Array (VGA), Super VGA (S-VGA), Digital Visual Interface (DVI), High-Definition Multimedia Interface (HDMI), or other appropriate technology. The display device interface 4420 may communicate display data from the processor 4410 to the display device 4422 for display by the display device 4422. As shown in FIG. 44, the display device 4422 may be external to the computing device 4400 and coupled to the computing device 4400 via the display device interface 4420. Alternatively, the display device 4422 may be included in the computing device 4400.

An instance of the computing device 4400 of FIG. 44 may be configured to perform any feature or any combination of features described above. In such an instance, the memory device 4416 and/or the storage device 4414 may store instructions which, when executed by the processor 4410, cause the processor 4410 to perform any feature or any combination of features described in the process above. Alternatively or additionally, in such an instance, each or any of the features described above may be performed by the processor 4410 in conjunction with the memory device 4416, communication interface 4412, peripheral device interface 4418, display device interface 4420, and/or storage device 4414.

Although FIG. 44 shows that the computing device 4400 includes a single processor 4410, single memory device 4416, single communication interface 4412, single peripheral device interface 4418, single display device interface 4420, and single storage device 4414, the computing device may include multiples of each or any combination of these components, and may be configured to perform, mutatis mutandis, analogous functionality to that described above.

As used herein, the term “processor” broadly refers to and is not limited to a single- or multi-core processor, a special purpose processor, a conventional processor, a Graphics Processing Unit (GPU), a digital signal processor (DSP), a plurality of microprocessors, one or more microprocessors in association with a DSP core, a controller, a microcontroller, one or more Application Specific Integrated Circuits (ASICs), one or more Field Programmable Gate Array (FPGA) circuits, any other type of integrated circuit (IC), a system-on-a-chip (SOC), and/or a state machine.

The methods or flow charts provided herein can be implemented in a computer program, software, or firmware incorporated in a non-transitory computer-readable storage medium for execution by a general purpose computer or a processor. As used herein, the term “computer-readable medium” broadly refers to and is not limited to a register, a cache memory, a ROM, a semiconductor memory device (such as a D-RAM, S-RAM, or other RAM), a magnetic medium such as a flash memory, a hard disk, a magneto-optical medium, an optical medium such as a CD-ROM, a DVD, or BLURAY-DISC, or other type of device for electronic data storage. For example, the methods described above may be implemented in the processor 4410 or on any other processor in the computing device 4400.

What is claimed is:

1. A unit device comprising:
a plurality of assemblies, each assembly of the plurality of assemblies configured to perform a general building function or a specific building function, wherein multiple assemblies perform the same general building function and one assembly performs each specific building function, wherein the plurality of assemblies are combined to form at least one of a studio unit, a one bedroom unit, and a two bedroom unit.

2. The unit device of claim 1, wherein the plurality of assemblies are selected from an assembly library.

3. The unit device of claim 1, wherein the general building functions of the unit include wall panels and floor panels.

4. The unit device of claim 1, wherein the specific building functions of the unit include a bathroom and a kitchen.

5. The unit device of claim 1, wherein at least one assembly of the plurality of assemblies is prefabricated.

6. The unit device of claim 1, wherein each assembly is considered at least one of standard, configurable, automated, or custom.

7. The unit device of claim 6, wherein a standard assembly includes elements that are fixed by the building system.

8. The unit device of claim 6, wherein a configurable assembly includes elements that have different options within the building system.

9. The unit device of claim 6, wherein an automated assembly includes elements that are unique to the building system and are resolved during a design phase of the building system.

10. The unit device of claim 6, wherein a custom assembly includes elements that are designed for a particular project.

11. A method of forming a unit device comprising:
forming a plurality of assemblies, each assembly of the plurality of assemblies configured to perform a general building function or a specific building function, wherein multiple assemblies perform the same general building function and one assembly performs each specific building function;
selecting assemblies from the plurality of assemblies; and
combining the selected assemblies to form at least one of a studio unit, a one bedroom unit, and a two bedroom unit.

12. The method of claim 11, wherein the plurality of assemblies are selected from an assembly library.

13. The method of claim 11, wherein the general building functions of the unit include wall panels and floor panels.

14. The method of claim 11, wherein the specific building functions of the unit include a bathroom and a kitchen.

15. The method of claim 11, wherein each assembly is considered at least one of standard, configurable, automated, or custom.

16. The method of claim 15, wherein a standard assembly includes elements that are fixed by the building system.

17. The method of claim 15, wherein a configurable assembly includes elements that have different options within the building system.

18. The method of claim 15, wherein an automated assembly includes elements that are unique to the building system and are resolved during a design phase of the building system.

19. The method of claim 15, wherein a custom assembly includes elements that are designed for a particular project.

20. A non-transitory computer-readable medium comprising a computer program product recorded thereon and capable of being run by a processor, including program code instructions for a process for creating a unit by implementing steps comprising:
forming a plurality of assemblies, each assembly of the plurality of assemblies configured to perform a general building function or a specific building function, wherein multiple assemblies perform the same general building function and one assembly performs each specific building function;
selecting assemblies from the plurality of assemblies; and
combining the selected assemblies to form at least one of a studio unit, a one bedroom unit, and a two bedroom unit.
